(19) United States
(12) Patent Application Publication
(10) Pub. No.: US 2026/0148681 A1
(43) Pub. Date: May 28, 2026

(54) DISPLAY PANEL AND ELECTRONIC DEVICE INCLUDING THE SAME

(71) Applicant: Samsung Display Co., Ltd., Yongin-si (KR)

(72) Inventors: Minsoo Kim, Yongin-si (KR); Jonghyun Choi, Yongin-si (KR)

(21) Appl. No.: 19/232,702

(22) Filed: Jun. 9, 2025

(30) Foreign Application Priority Data
Nov. 27, 2024 (KR) 10-2024-0172762

(51) Int. Cl. G09G 3/32

(52) U.S. Cl. CPC G09G 3/32; G09G 2300/0426; G09G 2300/0842

(57) ABSTRACT

A display panel includes: a substrate comprising a component area, a main display area at least partially surrounding the component area, and a non-display area at least partially surrounding the main display area; main pixels in the main display area, comprising main light-emitting diodes, and configured to perform active matrix driving; auxiliary pixels in the component area, comprising auxiliary light-emitting diodes, and configured to perform passive matrix driving; and a driver in the non-display area and comprising a scan driver and a data driver, wherein the auxiliary light-emitting diodes of the auxiliary pixels are directly connected to the driver.

### CROSS-REFERENCE TO RELATED APPLICATION

The present application claims priority to and the benefit of Korean Patent Application No. 10-2024-0172762, filed on Nov. 27, 2024, in the Korean Intellectual Property Office, the entire disclosure of which is incorporated herein by reference.

### BACKGROUND

### 1. Field

Aspects of one or more embodiments relate to a display panel and an electronic device including the same.

### 2. Description of the Related Art

An electronic device may include a display panel and components under the display panel. The components may include a sensor and a camera and may emit and/or detect light such as visible light and/or infrared light. The display panel may have a relatively high transmittance in an area (hereinafter, a component area) overlapping the components in order to ensure operations of the components.

The display panel may include pixels including a light-emitting diode as a display element. The pixels of the display panel may perform active matrix (AM) driving or passive matrix (PM) driving. In the case of AM driving, at least one thin-film transistor for controlling an operation of a light-emitting diode may be provided in each pixel. In the case of PM driving, electrodes directly connected to a driving unit (i.e., a driver) and intersecting each other may be provided, an emission layer may be located between electrodes in an area where the electrodes intersect and overlap each other, and the emission layer may emit light when a voltage is applied to the electrodes by the driving unit.

The above information disclosed in this Background section is only for enhancement of understanding of the background and therefore the information discussed in this Background section does not necessarily constitute prior art.

### SUMMARY

Aspects of one or more embodiments include a display panel having a relatively high transmittance in a component area.

Additional aspects will be set forth in part in the description which follows and, in part, will be apparent from the description, or may be learned by practice of the presented embodiments.

According to one or more embodiments, a display panel includes a substrate including a component area, a main display area at least partially surrounding the component area, and a non-display area at least partially surrounding the main display area, main pixels in the main display area, including main light-emitting diodes, and configured to perform active matrix driving, auxiliary pixels in the component area, including auxiliary light-emitting diodes, and configured to perform passive matrix driving, and a driver in the non-display area and including a scan driver and a data driver, wherein the auxiliary light-emitting diodes of the auxiliary pixels are directly connected to the driver.

According to some embodiments, the display panel may further include a plurality of first electrodes spaced apart from each other in the component area and extending in a first direction, a plurality of auxiliary scan lines connecting the plurality of first electrodes to the scan driver, a plurality of second electrodes spaced apart from each other in the component area and extending in a second direction intersecting the first direction, and a plurality of auxiliary data lines connecting the plurality of second electrodes to the data driver, wherein the auxiliary light-emitting diodes are in areas where the plurality of first electrodes and the plurality of second electrodes intersect each other.

According to some embodiments, one of the auxiliary light-emitting diodes may include an auxiliary pixel electrode in an area where one of the plurality of first electrodes and one of the plurality of second electrodes intersect each other, an auxiliary intermediate layer on the auxiliary pixel electrode, and a portion of the first electrode overlapping the auxiliary pixel electrode.

According to some embodiments, the display panel may further include a bank layer on the auxiliary pixel electrode and covering an edge portion of the auxiliary pixel electrode, wherein the plurality of first electrodes are spaced apart from each other with the bank layer therebetween.

According to some embodiments, the bank layer may include a first bank layer and a second bank layer on the first bank layer, wherein the plurality of first electrodes cover a part of the first bank layer and are spaced apart from each other with the second bank layer therebetween.

According to some embodiments, the display panel may further include an anti-adhesive layer on a top surface of the bank layer.

According to some embodiments, the second electrode may be under the auxiliary pixel electrode, wherein one of the plurality of auxiliary data lines is under the second electrode, and the auxiliary pixel electrode is connected to the auxiliary data line through the second electrode.

According to some embodiments, the second electrode may be integrally formed with the auxiliary pixel electrode.

According to some embodiments, the second electrode may be integrally formed with one of the plurality of auxiliary data lines.

According to some embodiments, a width of each of the plurality of first electrodes and each of the plurality of second electrodes in a first portion where the plurality of first electrodes and the plurality of second electrodes intersect each other may be greater than a width of each of the plurality of first electrodes and each of the plurality of second electrodes in a second portion other than the first portion.

According to some embodiments, at least some of the plurality of auxiliary scan lines may extend along a circumference of the main display area and may be connected to the scan driver.

According to some embodiments, the auxiliary light-emitting diodes may be individually connected to the data driver.

According to some embodiments, the display panel may further include a first electrode in the component area and extending in a first direction, wherein a plurality of auxiliary light-emitting diodes overlap the first electrode, and the plurality of auxiliary light-emitting diodes overlapping the first electrode are connected together to the scan driver through the first electrode.

According to some embodiments, each of the main light-emitting diodes may include a main pixel electrode, a main intermediate layer on the main pixel electrode, and a counter electrode on the main intermediate layer, and the auxiliary light-emitting diodes may be separated from the scan driver and may be connected to the counter electrode.

According to some embodiments, the driver may further include an auxiliary driver, wherein the auxiliary light-emitting diodes of the auxiliary pixels are separated from the scan driver and the data driver and are connected to the auxiliary driver.

According to some embodiments, the display panel may further include at least one dummy driving line adjacent to the component area, connected to the driver, and separated from the main pixels and the auxiliary pixels.

According to one or more embodiments, a display panel includes a substrate including a component area, a main display area at least partially surrounding the component area, and a non-display area at least partially surrounding the main display area, a main light-emitting diode in the main display area, an auxiliary light-emitting diode in the component area, and a driver in the non-display area and including a scan driver and a data driver, wherein the main light-emitting diode is connected to the driver through a pixel circuit including at least one thin-film transistor, and the auxiliary light-emitting diode is directly connected to the driver.

According to one or more embodiments, an electronic device includes a display panel, wherein the display panel includes a substrate including a component area, a main display area at least partially surrounding the component area, and a non-display area at least partially surrounding the main display area, main pixels in the main display area, including main light-emitting diodes, and configured to perform active matrix driving, auxiliary pixels in the component area, including auxiliary light-emitting diodes, and configured to perform passive matrix driving, and a driver in the non-display area and including a scan driver and a data driver, wherein the auxiliary light-emitting diodes of the auxiliary pixels are directly connected to the driver.

According to some embodiments, the display panel may further include a plurality of first electrodes spaced apart from each other in the component area and extending in a first direction, a plurality of auxiliary scan lines connecting the plurality of first electrodes to the scan driver, a plurality of second electrodes spaced apart from each other in the component area and extending in a second direction intersecting the first direction, and a plurality of auxiliary data lines connecting the plurality of second electrodes to the data driver, wherein the auxiliary light-emitting diodes are in areas where the plurality of first electrodes and the plurality of second areas intersect each other.

According to some embodiments, the auxiliary light-emitting diodes may be individually connected to the data driver.

### BRIEF DESCRIPTION OF THE DRAWINGS

The above and other aspects, features, and advantages of certain embodiments will be more apparent from the following description taken in conjunction with the accompanying drawings, in which:

FIG. 1 is a block diagram illustrating an electronic device, according to some embodiments;

FIGS. 2, 3, and 4 are schematic views illustrating an electronic device, according to some embodiments;

FIG. 5 is a perspective view illustrating an electronic device, according to some embodiments;

FIG. 6 is an exploded perspective view illustrating an electronic device, according to some embodiments;

FIG. 7 is a schematic plan view illustrating a display panel, according to some embodiments;

FIG. 8 is a schematic cross-sectional view illustrating the display panel taken along the line VII-VII′ of FIG. 7;

FIG. 9 is a plan view illustrating a display panel, according to some embodiments;

FIG. 10 is a plan view illustrating a display panel, according to some embodiments;

FIG. 11 is a schematic circuit diagram illustrating a main light-emitting diode provided in a main pixel and a pixel circuit connected to the main light-emitting diode, according to some embodiments;

FIG. 12A is an enlarged plan view illustrating a portion of a display panel, according to some embodiments;

FIG. 12B is an enlarged plan view illustrating a portion of a display panel, according to some embodiments;

FIG. 13A is a cross-sectional view illustrating a display panel, according to some embodiments;

FIG. 13B is a cross-sectional view illustrating a display panel, according to some embodiments;

FIG. 14A is a cross-sectional view illustrating a display panel, according to some embodiments;

FIG. 14B is a cross-sectional view illustrating a display panel, according to some embodiments;

FIG. 15 is a cross-sectional view illustrating a display panel, according to some embodiments;

FIG. 16 is a cross-sectional view illustrating a display panel, according to some embodiments;

FIG. 17 is a cross-sectional view illustrating a display panel, according to some embodiments;

FIG. 18 is an enlarged plan view illustrating a portion of a display panel, according to some embodiments;

FIG. 19 is an enlarged plan view illustrating a display panel, according to some embodiments;

FIG. 20 is an enlarged plan view illustrating a portion of a display panel, according to some embodiments;

FIG. 21 is an enlarged plan view illustrating a portion of a display panel, according to some embodiments;

FIG. 22A is an enlarged plan view illustrating a portion of a display panel, according to some embodiments;

FIG. 22B is a cross-sectional view illustrating the display panel taken along the line C-C′ of FIG. 22A;

FIG. 23 is an enlarged plan view illustrating a portion of a display panel, according to some embodiments;

FIG. 24 is an enlarged plan view illustrating a portion of a display panel, according to some embodiments; and

FIG. 25 is an enlarged plan view illustrating a portion of a display panel, according to some embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

As the disclosure allows for various changes and numerous embodiments, certain embodiments will be illustrated in the drawings and described in the detailed description. Effects and features of the disclosure, and methods for achieving them will be clarified with reference to embodiments described below in detail with reference to the drawings. However, the disclosure is not limited to the following embodiments and may be embodied in various forms.

Hereinafter, embodiments will be described in detail with reference to the accompanying drawings, wherein the same or corresponding elements are denoted by the same reference numerals throughout and a repeated description thereof is omitted.

It will be understood that when a component, such as a layer, a film, a region, or a plate, is referred to as being “on” another component, the component may be directly on the other component or intervening components may be present therebetween. Also, sizes of components in the drawings may be exaggerated or reduced for convenience of explanation. For example, because sizes and thicknesses of components in the drawings are arbitrarily illustrated for convenience of explanation, the disclosure is not limited thereto.

In the following embodiments, the x-axis, the y-axis and the z-axis are not limited to three axes of the rectangular coordinate system, and may be interpreted in a broader sense. For example, the x-axis, the y-axis, and the z-axis may be perpendicular to one another or may represent different directions that are not perpendicular to one another.

Although the terms “first,” “second,” etc. may be used to describe various elements, these elements should not be limited by these terms. These terms are only used to distinguish one element from another.

It will be further understood that the terms “comprises” or “comprising” used herein specify the presence of stated features or components, but do not preclude the presence or addition of one or more other features or components.

The expression “A and/or B” as herein indicates only A, only B, or both A and B. The expression “at least one of A and B” as used herein indicates only A, only B, or both A and B.

It will be understood that when a layer, region, or component is referred to as being “connected,” the layer, the region, or the component may be directly connected or may be indirectly connected with intervening layers, regions, or components therebetween. For example, when layers, regions, or components are referred to as being “electrically connected,” the layers, the regions, or the components may be directly electrically connected, or may be indirectly electrically connected with intervening layers, regions, or components therebetween.

A display apparatus according to embodiments may be applied to various electronic devices. An electronic device according to some embodiments may include a display apparatus, and may further include a module or a device having an additional function in addition to the display apparatus. A display apparatus according to some embodiments may include a display panel.

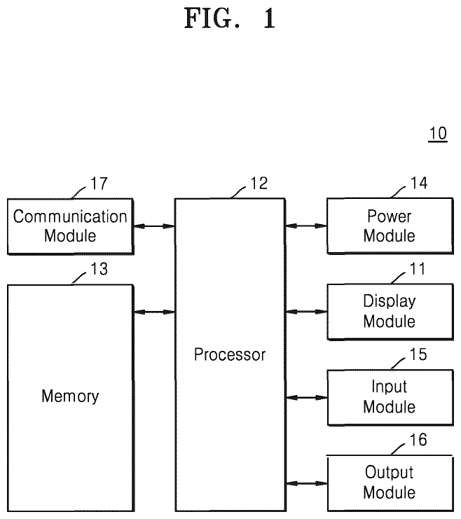

FIG. 1 is a block diagram illustrating an electronic device, according to some embodiments. Referring to FIG. 1, an electronic device 10 may include a display panel 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller. According to some embodiments, the processor 12 may be divided into two or more processors from a functional or structural point of view. For example, the processor 12 may include a main processor as a first driving chip including a CPU and an auxiliary processor as a second driving chip including a controller that receives an image signal from the main processor and processes the image signal to meet interface specifications of the display panel 11.

The memory 13 may include at least one of a non-volatile memory or a volatile memory. The memory 13 may store data information necessary for an operation of the processor 12 or the display panel 11. When the processor 12 executes an application stored in the memory 13, an image data signal and/or an input control signal may be transmitted to the display panel 11, and the display panel 11 may processor the received signal and may output image information through a display screen.

The power module 14 may include a power supply module, such as a power adaptor or a battery device, and a power conversion module configured to convert power supplied by the power supply module and generate power necessary for an operation of the electronic device 10. Power conversion by the power conversion module may include, but is not limited to, direct current (DC)-DC conversion, alternating current (AC)-DC conversion, and DC-AC conversion.

The electronic device 10 may further include an input module 15, a non-image output module 16, and/or a communication module 17.

The input module 15 may provide input information to the processor 12 and/or the display panel 11. The input module 15 may include not only a physical button, a keyboard, and a microphone but also various sensor modules. Examples of the sensor modules may include not only a touch sensor, a pressure sensor, a distance sensor, a position sensor, a digitizer, a motion recognition sensor, a camera sensor, a light reception sensor, a photoelectric conversion sensor, and a temperature sensor, but also biometric sensors such as a blood pressure sensor, a blood sugar sensor, an electrocardiogram sensor, and a heart rate sensor.

The non-image output module 16 may receive information other than an image received from the processor 12 and may provide the information to a user. Examples of the non-image output module 16 may include a sound module, a haptic module, and a light-emitting module, and may also include other functionally intrinsic modules (e.g., a cooling module of a refrigerator) of an electronic device.

The communication module 17 is a module for transmitting/receiving information between the electronic device 10 and an external device, and may include a receiver and a transmitter. The communication module 17 may include various wireless communication modules, such as a mobile communication module, a Wi-Fi module, and a Bluetooth module, or various wired communication modules.

At least one of the components of the electronic device 10 described above may be included in a display apparatus. Also, some of individual modules functionally included in one module may be included in the display apparatus and the others may be provided separately from the display apparatus. For example, the display apparatus may include the display panel 11, and the processor 12, the memory 13, and the power module 14 may be provided as other devices in the electronic device 10, rather than the display apparatus. In another example, the power module 14 may be provided in the display apparatus, and may supply power to the processor 12 and the memory 13 provided in the electronic device 10, rather than the display apparatus. However, the disclosure is not limited thereto.

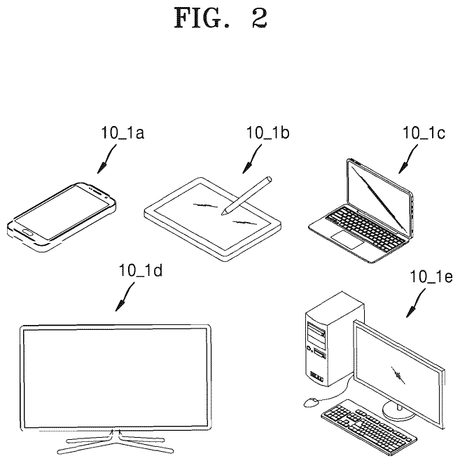

FIGS. 2 to 4 are schematic views illustrating an electronic device, according to various embodiments. FIGS. 2 to 4 illustrate examples of various electronic devices to which a display apparatus is applied, according to various embodiments.

FIG. 2 illustrates a smartphone 10_1a, a tablet PC 10_1b, a laptop computer 10_1c, a TV 10_1d, and a monitor 10_1e for a desk as examples of an electronic device.

The smartphone 10_1a may include an input module, such as a touch sensor, and a communication module, in addition to a display panel. The smartphone 10_1a may process information received through the communication module or other input modules and may display the information through the display panel of the display apparatus.

Each of the table PC 10_1b, the laptop computer 10_1c, the TV 10_1d, and the monitor 10_1e for a desk may also include a display panel and an input module, like the smartphone 10_1a, and may further include a communication module when necessary.

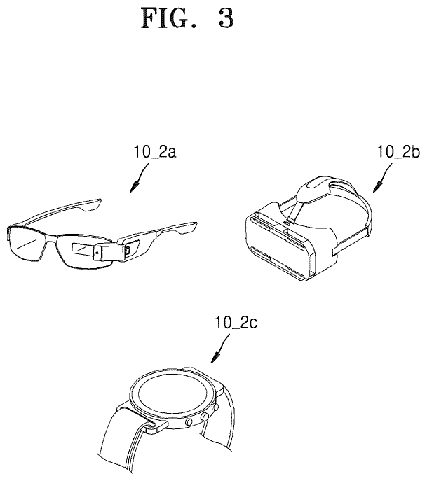

FIG. 3 illustrates a case where an electronic device including a display panel is applied to a wearable electronic device. Examples of the wearable electronic device may include smart gasses 10_2a, a head mounted display 10_2b, and a smart watch 10_2c.

The smart glasses 10_2a and the head mounted display 10_2b may include a display panel that emits a display image and a reflector that reflects the emitted display screen and provides the display screen to a user's eyes, thereby providing a screen of virtual reality or augmented reality to the user.

The smart watch 10_2c may include a biometric sensor as an input device, and may provide biometric information recognized through the biometric sensor to the user through a display panel.

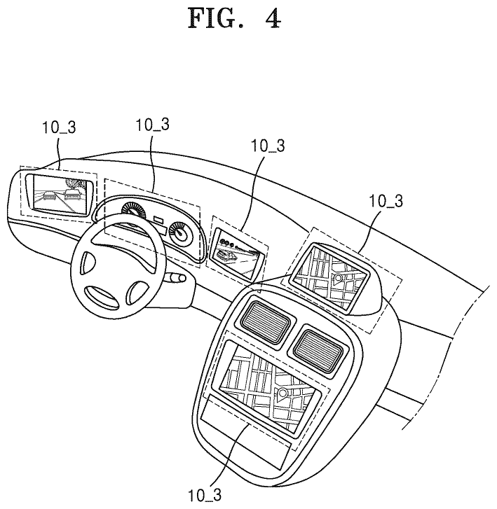

FIG. 4 illustrates a case where an electronic device including a display panel is applied to a vehicle. For example, an electronic device 10_3 may be applied to a dashboard or a center fascia of a vehicle, or may be applied to a center information display (CID) located on a dashboard of a vehicle or a room mirror display that replaces a side-view mirror.

According to some embodiments, examples of an electronic device to which a display apparatus according to embodiments is applied may include not only devices that mainly display screens, such as an advertisement board, an electronic display board, and a game console, but also various home appliances that display information through a display panel, such as a refrigerator, a washing machine, a drier, an air conditioner, and a robot cleaner. Also, when a display panel has a function of transmitting light, the display panel may be applied to an electronic device such as a smart window or a transparent display apparatus that displays both a background and a display image. Types of an electronic device according to some embodiments are not limited to the examples described above, and various other electronic devices may also be provided.

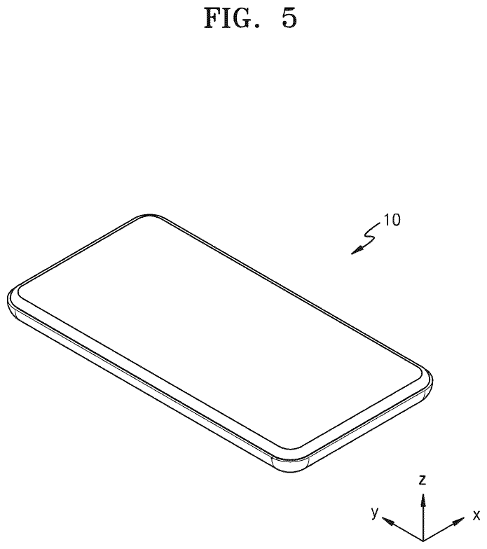

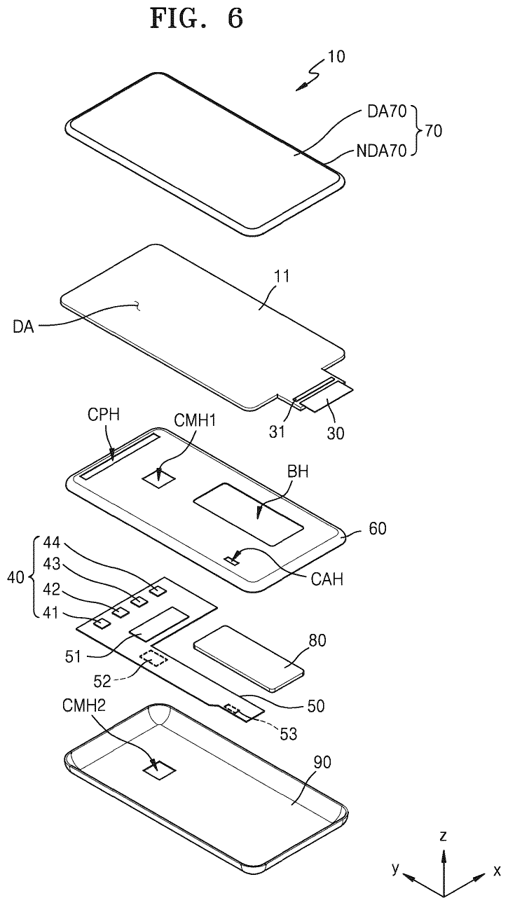

FIG. 5 is a perspective view illustrating the electronic device 10, according to some embodiments. FIG. 6 is an exploded perspective view illustrating the electronic device 10, according to some embodiments.

Referring to FIGS. 5 and 6, for convenience of explanation, embodiments where the electronic device 10 is a smartphone is illustrated and will be mainly described. However, embodiments according to the present disclosure are not limited thereto, and may be applied to various electronic devices as described above.

According to some embodiments, the electronic device 10 may include the display panel 11, a data driver 31, a display circuit board 30, components 40, a main circuit board 50, a bracket 60, a cover window 70, a battery 80, and a lower cover 90.

The electronic device 10 may have a rectangular shape in a plan view. For example, as shown in FIG. 5, the electronic device 10 may have a rectangular shape having a short side in an x direction and a long side in a y direction in a plan view. A corner where the short side in the x direction and the long side in the y direction meet each other may be rounded to have a certain curvature or formed to have a right angle. A planar shape of the electronic device 10 is not limited to a rectangular shape, and may be any of other shapes such as a polygonal shape, an elliptical shape, or an irregular shape.

The cover window 70 may be located on the display panel 11 to cover a top surface of the display panel 11. Accordingly, the cover window 70 may protect the top surface of the display panel 11.

The cover window 70 may include a transmissive cover portion DA70 corresponding to the display panel 11 and a light-blocking cover portion NDA70 surrounding the transmissive cover portion DA70. The light-blocking cover portion NDA70 may include an opaque material for blocking light (e.g., a colored opaque material). The light-blocking cover portion NDA70 may include a pattern that may be shown to a user when an image is not displayed. The display panel 11 may be located under the cover window 70. The display panel 11 may overlap the transmissive cover portion DA70 of the cover window 70.

The display panel 11 may include a display area DA. The display area DA may be an area where an image is displayed. The display area DA may include an area (hereinafter, referred to as a component area) through which light emitted from the components 40 located under the display panel 11 is transmitted. The components 40 may include external modules such as a sensor and a camera using visible light, infrared light, or sound. According to some embodiments, the components 40 may be included in the input module 15 described with reference to FIG. 1.

The display panel 11 may be a light-emitting display panel including a light-emitting diode. According to some embodiments, the light-emitting diode may include an organic light-emitting diode including an organic emission layer. According to some embodiments, the light-emitting diode may include an inorganic light-emitting diode including an inorganic material. The inorganic light-emitting diode may include a PN diode including inorganic semiconductor-based materials. When a voltage is applied to a PN junction diode in a forward direction, holes and electrons may be injected, and energy generated by recombination of the holes and electrons may be converted into light energy to emit light of a certain color. The inorganic light-emitting diode may have a width of several to hundreds of micrometers, and in some embodiments, the inorganic light-emitting diode may be referred to as a micro-LED. Although embodiments where the light-emitting diode of the display panel 11 is an organic light-emitting diode will be mainly described for convenience of explanation, embodiments according to the present disclosure are not limited thereto.

The display panel 11 may be a rigid display panel that is rigid and is not easily bent, or a flexible display panel that is flexible and may be easily bent, folded, or rolled. For example, the display panel 11 may be a foldable display panel that may be folded and unfolded, a curved display panel having a curved display surface, a bended display panel in which a portion other than a display surface is bent, a rollable display panel that may be rolled or unrolled, and/or a stretchable display panel that may be stretched.

The display panel 11 may be a transparent display panel that is transparent so that an object or a background located on a bottom surface of the display panel 11 is viewed from the top surface of the display panel 11. Alternatively, the display panel 11 may be a reflective display panel capable of reflecting an object or a background on the top surface of the display panel 11.

The data driver 31 may be formed as an integrated circuit (IC) on the display panel 11. According to some embodiments, the data driver 31 may be located on the display circuit board 30.

The display circuit board 30 may be attached to one side of the display panel 11. The display circuit board 30 may be a flexible printed circuit board (FPCB) that may be bent, a rigid printed circuit board (PCB) that is hard and not easily bent, or a composite printed circuit board including both a rigid printed circuit board and a flexible printed circuit board. According to some embodiments, the display circuit board 30 may be included in the processor 12 described with reference to FIG. 1.

According to some embodiments, a touch sensor driver may be located on the display circuit board 30. The touch sensor driver may include an IC. The touch sensor driver may be attached to the display circuit board 30. The touch sensor driver may be electrically connected to touch electrodes of a touchscreen layer of the display panel 11 through the display circuit board 30.

The touchscreen layer of the display panel 11 may detect a touch input of the user by using at least one of various touch methods such as a resistive method or a capacitive method. For example, when the touchscreen layer of the display panel 11 detects a touch input of the user by using a capacitive method, the touch sensor driver may determine whether the user touches by applying driving signals to driving electrodes from among the touch electrodes and detecting voltages charged in mutual capacitance between the driving electrodes and sensing electrodes through the sensing electrodes from among the touch electrodes. The user's touch may include a contact touch and a proximity touch. The contact touch means that an object such as the user's finger or a pen directly contacts the cover window 70 located on the touchscreen layer. The proximity touch means that an object such as the user's finger or a pen is located close to the cover window 70, such as hovering. The touch sensor driver may transmit sensor data to a main processor according to the detected voltages, and the main processor may calculate touch coordinates where the touch input occurs by analyzing the sensor data. According to some embodiments, the touchscreen layer of the display panel 11 may be included in the input module 15 described with reference to FIG. 1.

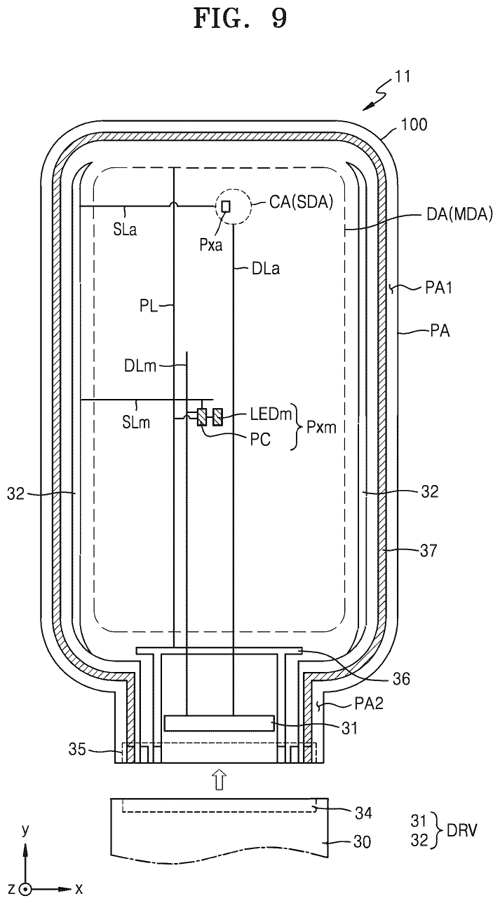

A processor for supplying driving voltages for driving pixels (e.g., Pxm and Pxa (see FIG. 9)) of the display panel 11, a scan driver 32 (see FIG. 9), and a data driver 31 may be located on the display circuit board 30.

The bracket 60 for supporting the display panel 11 may be located under the display panel 11. The bracket 60 may include plastic, metal, or both plastic and metal. A first camera hole CMH1 into which a camera module 51 is inserted, a battery hole BH in which the battery 80 is located, and a cable hole CAH through which a cable connected to the display circuit board 30 passes may be formed in the bracket 60. A component hole CPH overlapping the display panel 11 may be formed in the bracket 60. The component hole CPH may overlap the components 40 of the main circuit board 50 in a z direction. According to some embodiments, the display area DA of the display panel 11 may overlap the components 40 of the main circuit board 50 in the z direction. According to some embodiments, the component hole CPH may not be formed in the bracket 60.

According to some embodiments, the components 40 may include first to fourth components 41, 42, 43, and 44 overlapping the display panel 11. The first to fourth components 41, 42, 43, and 44 may be respectively provided as a proximity sensor, an illumination sensor, an iris sensor, a facial recognition sensor, and a camera (or an image sensor). The proximity sensor using infrared rays may detect an object located close to a top surface of the electronic device 10, and the illumination sensor may detect a brightness of light incident on the top surface of the electronic device 10. Also, the iris sensor may capture an image of an iris of a person arranged over the top surface of the electronic device 10, and the camera may capture an image of the object located over the top surface of the electronic device 10. The components 40 are not limited to the proximity sensor, the illumination sensor, the iris sensor, the facial recognition sensor, and the camera, and various modules may be arranged.

The main circuit board 50 and the battery 80 may be located under the bracket 60. The main circuit board 50 may be a printed circuit board or a flexible printed circuit board. According to some embodiments, the battery 80 may be included in the power module 14 described with reference to FIG. 1.

The main circuit board 50 may include the camera module 51, a main processor 52, a main connector 53, and the components 40. The main processor 52 may include an IC. The camera module 51 may be located on both a top surface and a bottom surface of the main circuit board 50. Each of the main processor 52 and the main connector 53 may be located on any one of the top surface and the bottom surface of the main circuit board 50. According to some embodiments, the main processor 52 may be included in the processor 12 described with reference to FIG. 1.

The camera module 51 may process an image frame such as a still image or a moving image obtained by an image sensor in a camera mode and may output the image frame to the main processor 52. The camera module 51 may include at least one of a camera sensor (e.g., CCD or CMOS), a photo sensor (or image sensor), or a laser sensor. According to some embodiments, the camera module 51 may be connected to the image sensor (e.g., the fourth component 44) from among the components 40 and may process an image input to the image sensor. According to some embodiments, the camera module 51 may be integrated with the component 40 (e.g., the fourth component 44). According to some embodiments, the camera module 51 may be included in the input module 15 described with reference to FIG. 1.

A cable passing through the cable hole CAH of the bracket 60 may be connected to the main connector 53, and thus, the main circuit board 50 may be electrically connected to the display circuit board 30. According to some embodiments, the main circuit board 50 and the display circuit board 30 may include a first driving chip (or the main processor 52) and a second driving chip (or an auxiliary processor) described with reference to FIG. 1.

The lower cover 90 may form an outer appearance of the electronic device 10, and an opening through which at least a part of the display panel 11 is exposed may be formed in a front surface of the lower cover 90. The lower cover 90 has a shape whose surface corresponding to the display panel 11 is open, and may be assembled to the display panel 11. The lower cover 90 may be located opposite to the cover window 70 with the display panel 11 therebetween. The lower cover 90 may be located under the main circuit board 50 and the battery 80. The lower cover 90 may be fastened and fixed to the bracket 60. The lower cover 90 may form an outer appearance of a bottom surface of the electronic device 10. The lower cover 90 may include plastic, metal, or both plastic and metal.

A second camera hole CMH2 through which a bottom surface of the camera module 51 is exposed may be formed in the lower cover 90. A position of the camera module 51 and positions of the first and second camera holes CMH1 and CMH2 corresponding to the camera module 51 are not limited to those illustrated in FIG. 6 and may be changed in various ways.

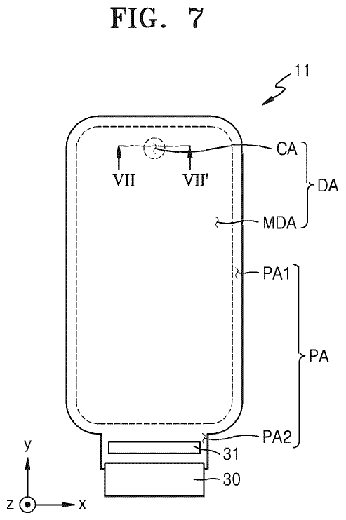

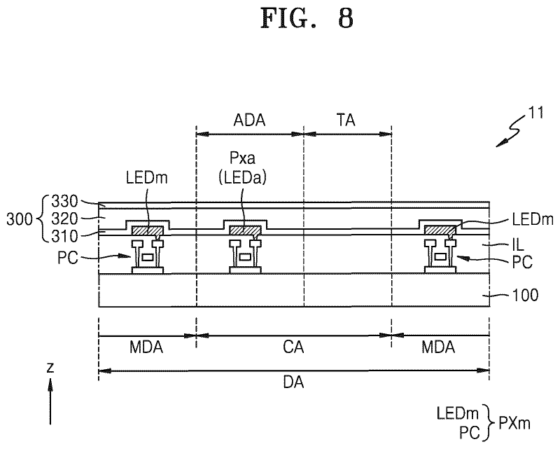

FIG. 7 is a schematic plan view illustrating the display panel 11, according to some embodiments. FIG. 8 is a schematic cross-sectional view illustrating the display panel 11 taken along the line VII-VII′ of FIG. 7.

Referring to FIGS. 7 and 8, the display panel 11 may include the display area DA and a peripheral area PA outside the display area DA. In the disclosure, when the display panel 11 includes a first area (e.g., the display area DA), it may substantially mean that a substrate 100 includes the first area (e.g., the display area DA) and the first area (e.g., the display area DA) is defined in the substrate 100.

When viewed in a plan view (e.g., when viewed in the z direction), the display area DA may have a substantially rectangular shape with rounded corners as shown in FIG. 7. However, the disclosure is not limited thereto, and the display area DA may have a polygonal shape such as a triangular shape, a pentagonal shape, or a hexagonal shape, a circular shape, an elliptical shape, or an irregular shape. Pixels including a light-emitting diode as a display element, for example, a main pixel Pxm and an auxiliary pixel Pxa, may be located in the display area DA. The display panel 11 may include a plurality of main pixels Pxm and a plurality of auxiliary pixels Pxa. The peripheral area PA may be a non-display area where pixels are not located. The peripheral area PA may at least partially (e.g., entirely) surround the display area DA.

The display area DA may include a main display area MDA and a component area CA. The main display area MDA may at least partially (e.g., entirely) surround the component area CA. However, the disclosure is not limited thereto, and various modifications may be made. For example, a part of the component area CA may contact the peripheral area PA.

In a plan view (e.g., when viewed in the z direction), the component area CA may have any of various shapes such as a polygonal shape (e.g., a triangular shape, a quadrangular shape, a pentagonal shape, or a hexagonal shape), a circular shape, an elliptical shape, a star shape, or an irregular shape. For convenience of explanation, embodiments where the component area CA has a circular shape is illustrated and will be mainly described.

Referring to FIG. 6 together, the component area CA may overlap the components 40 and the component hole CPH of the bracket 60. Although aspects of embodiments where the display area DA includes one component CA is illustrated in FIG. 7, embodiments according to the present disclosure are not limited thereto. According to some embodiments, the display panel 11 may include a plurality of component areas that are spaced apart from each other. Sizes of the plurality of component areas may be different from each other when necessary. According to some embodiments, the component area CA may be provided to simultaneously overlap the components 40. According to some embodiments, a plurality of component areas individually overlapping the first to fourth components 41, 42, 43, and 44 may be provided.

The component area CA may include an auxiliary display area ADA and a transmissive area TA. According to some embodiments, the auxiliary display area ADA may be an area in which the auxiliary pixel Pxa is located. According to some embodiments, the transmissive area TA may be a remaining area of the component area CA excluding the auxiliary display area ADA.

A main image may be displayed in the main display area MDA, and an auxiliary image may be displayed in the component area CA (e.g., the auxiliary display area ADA). For example, the main pixels Pxm for displaying a main image may be located in the main display area MDA, and the auxiliary pixels Pxa for displaying auxiliary images may be located in the auxiliary display area ADA of the component area CA.

The transmissive area TA may transmit light and/or sound output from the components 40 to the outside or traveling from the outside toward the components 40. According to some embodiments, a transmittance of the component area CA may be about 10% or more, about 20% or more, about 30% or more, about 40% or more, about 50% or more, about 60% or more, about 70% or more, about 75% or more, about 80% or more, about 85% or more, or about 90% or more. According to some embodiments, a transmittance of the component area CA may be determined by a transmittance of the transmissive area TA and a ratio (e.g., area ratio) of the transmissive area TA to the component area CA.

The peripheral area PA may include a first peripheral area PA1 surrounding at least a part of the display area DA and a second peripheral area PA2 located adjacent to one side of the display area DA and extending in the y direction. A width of the second peripheral area PA2 along the x direction may be less than a width of the display area DA. Through this structure, at least a part of the second peripheral area PA2 may be easily bent. According to some embodiments, the display panel 11 may be bent around a bending axis crossing the second peripheral area PA2.

Referring to FIG. 8, the display panel 11 may include the substrate 100, the main pixel Pxm and the auxiliary pixel Pxa on the substrate 100, and an encapsulation layer 300 on the main pixel Pxm and the auxiliary pixel Pxa. According to some embodiments, the display panel 11 may further include a touchscreen layer and/or an optical functional layer on the encapsulation layer 300.

The substrate 100 may include glass, a metal, or a polymer resin. According to some embodiments, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. However, various modifications may be made. For example, the substrate 100 may have a multi-layer structure including two layers each including a polymer resin and a barrier layer including an inorganic material (e.g., silicon oxide (SiO₂), silicon nitride (SiNₓ), or silicon oxynitride (SiON) and located between the two layers.

The main pixel Pxm and the auxiliary pixel Pxa may be located on the substrate 100. The main pixel Pxm may be located in the main display area MDA. The main pixel Pxm may include a main light-emitting diode LEDm and a pixel circuit PC. The main light-emitting diode LEDm may be (e.g., electrically) connected to the pixel circuit PC. The pixel circuit PC may include at least one thin-film transistor for driving the main light-emitting diode LEDm. The auxiliary pixel Pxa may be located in the component area CA, for example, the auxiliary display area ADA. The auxiliary pixel Pxa may include an auxiliary light-emitting diode LEDa. The auxiliary pixel Pxa may not include a pixel circuit or a thin-film transistor for driving the auxiliary light-emitting diode LEDa. Instead, the auxiliary pixel Pxa (or the auxiliary light-emitting diode LEDa) may be directly connected to a driver DRV (see FIG. 9) as described below. The pixel circuit PC may be located in an insulating layer IL located on the substrate 100. The main light-emitting diode LEDm and the auxiliary light-emitting diode LEDa may be located on the insulating layer IL. The insulating layer IL may include a plurality of layers described below.

The encapsulation layer 300 may cover the main light-emitting diode LEDm and the auxiliary light-emitting diode LEDa. The encapsulation layer 300 may include at least one inorganic layer and at least one organic layer. According to some embodiments, as shown in FIG. 8, the encapsulation layer 300 may include a first inorganic encapsulation layer 310, an organic encapsulation layer 320, and a second inorganic encapsulation layer 330. The organic encapsulation layer 320 may be located between the first inorganic encapsulation layer 310 and the second inorganic encapsulation layer 330.

Each of the first inorganic encapsulation layer 310 and the second inorganic encapsulation layer 330 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnOₓ). The organic encapsulation layer 320 may include a polymer-based material. Examples of the polymer-based material may include a silicone-based resin, an acrylic resin (e.g., polymethyl methacrylate or polyacrylic acid), an epoxy resin, polyimide, and polyethylene.

The first inorganic encapsulation layer 310, the organic encapsulation layer 320, and the second inorganic encapsulation layer 330 may be integrally formed to simultaneously cover the main display area MDA and the component area CA.

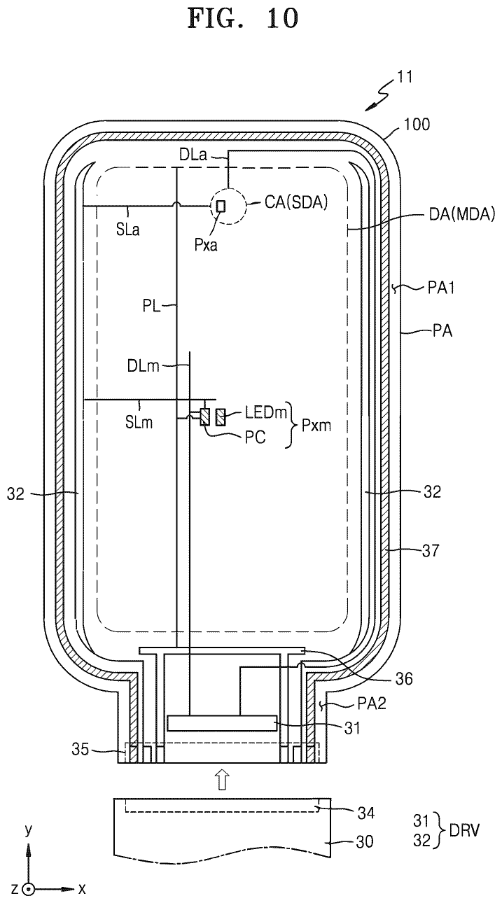

FIG. 9 is a plan view illustrating the display panel 11, according to some embodiments. FIG. 10 is a plan view illustrating the display panel 11, according to some embodiments.

Referring to FIGS. 9 and 10, in the peripheral area PA, the driver DRV including the data driver 31 and the scan driver 32, a pad unit 35, a driving voltage supply wiring 36, and a common voltage supply wiring 37 may be located.

A main data line DLm and an auxiliary data line DLa may be connected to the data driver 31. The main data line DLm may be connected to the main pixel Pxm. For example, the main data line DLm may be connected to the pixel circuit PC of the main pixel Pxm. The data driver 31 may provide a data signal to the main pixel Pxm (e.g., the pixel circuit PC of the main pixel Pxm) through the main data line DLm.

The auxiliary data line DLa may be connected to the auxiliary pixel Pxa. For example, the auxiliary data line DLa may be directly connected to the auxiliary light-emitting diode LEDa of the auxiliary pixel Pxa. In other words, the auxiliary light-emitting diode LEDa of the auxiliary pixel Pxa may be directly connected to the data driver 31 of the driver DRV through the auxiliary data line DLa. Accordingly, the data driver 31 may directly control driving of the auxiliary light-emitting diode LEDa of the auxiliary pixel Pxa.

A main scan line SLm and an auxiliary scan line SLa may be connected to the scan driver 32. The main scan line SLm may be connected to the main pixel Pxm. For example, the main scan line SLm may be connected to the pixel circuit PC of the main pixel Pxm. The scan driver 32 may provide a scan signal to the main pixel Pxm (e.g., the pixel circuit PC of the main pixel Pxm) through the main scan line SLm. The main scan line SLm may be a gate line connected to gates of switching transistors included in the pixel circuit PC of the main pixel Pxm. A scan signal may be a gate signal for turning on or turning off a switching transistor included in the pixel circuit PC.

The auxiliary scan line SLa may be connected to the auxiliary pixel Pxa. For example, the auxiliary scan line SLa may be directly connected to the auxiliary light-emitting diode LEDa of the auxiliary pixel Pxa. In other words, the auxiliary light-emitting diode LEDa of the auxiliary pixel Pxa may be directly connected to the scan driver 32 of the driver DRV through the auxiliary scan line SLa. Accordingly, the scan driver 32 may directly control driving of the auxiliary light-emitting diode LEDa of the auxiliary pixel Pxa.

Because the main data line DLm and the main scan line SLm may be connected to the main light-emitting diode LEDm through the pixel circuit PC of the main pixel Pxm, in the disclosure, when the main data line DLm and/or the main scan line SLm is connected to the main pixel Pxm, it may mean that the main data line DLm and/or the main scan line SLm is connected to the pixel circuit PC of the main pixel Pxm.

Because the auxiliary data line DLa and the auxiliary scan line SLa may be directly connected to the auxiliary light-emitting diode LEDa of the auxiliary pixel Pxa, in the disclosure, when the auxiliary data line DLa and/or the auxiliary scan line SLa is connected to the auxiliary pixel Pxa, it may mean that the auxiliary data line DLa and/or the auxiliary scan line SLa is connected to the auxiliary light-emitting diode LEDa of the auxiliary pixel Pxa.

The scan driver 32 may be located on both sides of the peripheral area PA (e.g., the first peripheral area PA1) with the display area DA (e.g., the main display area MDA) therebetween. Some of the main pixels Pxm and some of the auxiliary pixels Pxa may be electrically connected to the scan driver 32 arranged in a −x direction, and the rest may be electrically connected to the scan driver 32 arranged in a +x direction. According to some embodiments, the scan driver 32 may be located only on one side of the peripheral area PA (e.g., the first peripheral area PA1).

The pad unit 35 may be located in the second peripheral area PA2 of the display panel 11. The pad unit 35 may be exposed without being covered by an insulating layer, and may be electrically connected to the display circuit board 30. For example, a pad unit 34 of the display circuit board 30 and the pad unit 35 of the display panel 11 may be electrically connected.

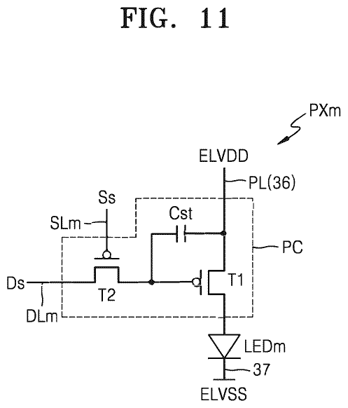

According to some embodiments, the display circuit board 30 may provide a control signal to the data driver 31 and the scan driver 32 of the driver DRV. According to some embodiments, the display circuit board 30 may include a power management IC. The power management IC may respectively provide a driving voltage ELVDD (see FIG. 11) and a common voltage ELVSS (see FIG. 11) to the driving voltage supply wiring 36 and the common voltage supply wiring 37. The driving voltage ELVDD may be provided to the pixel circuit PC of the main pixel Pxm through a driving voltage line PL connected to the driving voltage supply wiring 36. The common voltage ELVSS may be provided to a counter electrode of the main light-emitting diode LEDm through the common voltage supply wiring 37. The driving voltage supply wiring 36 may extend in the x direction. The common voltage supply wiring 37 may have a loop shape with one side open and may partially surround the display area DA.

The data driver 31 may be arranged in a −y direction of the display area DA (e.g., the main display area MDA). The main data line DLm may extend along the y direction across the display area DA (e.g., the main display area MDA) and may be connected to a corresponding main pixel Pxm. The scan driver 32 may be arranged in the +x direction and the −x direction of the display area DA (e.g., the main display area MDA). The main scan line SLm may extend along the x direction across the display area DA (e.g., the main display area MDA) and may be connected to a corresponding main pixel Pxm. Likewise, the auxiliary scan line SLa may extend along the x direction across the display area DA (e.g., the main display area MDA) and may be connected to a corresponding auxiliary pixel Pxa.

Referring to FIG. 9, the auxiliary data line DLa may extend along the y direction across the display area DA (e.g., the main display are MDA) and may be connected to a corresponding auxiliary pixel Pxa, like the main data line DLm. According to some embodiments, the auxiliary data DLa may approach the component area CA from the −y direction of the component area CA.

Referring to FIG. 10, the auxiliary data line DLa may extend by bypassing the display area DA. For example, the auxiliary data line DLa may be connected to the data driver 31 and may extend in the peripheral area PA, and may approach the component area CA and the auxiliary pixel Pxa from a +y direction of the component area CA. According to some embodiments, a part of the auxiliary data line DLa may be located between the scan driver 32 and the common voltage supply wiring 37. FIG. 10 illustrates embodiments where the auxiliary data line DLa is arranged in the +x direction of the display area DA (e.g., the main display area MDA). According to some embodiments, the auxiliary data line DLa may be arranged in the −x direction or both the +x direction and the −x direction of the display area DA (e.g., the main display area MDA). For convenience of explanation, a case where the auxiliary data line DLa approaches the component area CA from the +y direction as in FIG. 10 is illustrated and described, but the disclosure is not limited thereto.

FIG. 11 is a schematic circuit diagram illustrating the main light-emitting diode LEDm provided in the main pixel Pxm and the pixel circuit PC connected to the main light-emitting diode LEDm, according to some embodiments. Although FIG. 11 illustrates various components in a pixel circuit according to some embodiments, embodiments according to the present disclosure are not limited thereto, and according to various embodiments, the pixel circuit may include additional components or fewer components without departing from the spirit and scope of embodiments according to the present disclosure.

Referring to FIG. 11, the pixel circuit PC may be connected to the main light-emitting diode LEDm and may control light emission of the main pixel Pxm. The pixel circuit PC may include a first transistor T1, a second transistor T2, and a storage capacitor Cst. According to some embodiments, the first transistor T1 may be a driving transistor, and the second transistor T2 may be a switching transistor. The second transistor T2 may be connected to the main scan line SLm and the main data line DLm, and may transmit a data signal Ds input through the main data line DLm to the first transistor T1 according to a scan signal Ss input through the main scan line SLm.

The storage capacitor Cst may be connected to the second transistor T2 and the driving voltage line PL, and may store a voltage corresponding to a difference between a voltage received from the second transistor T2 and the driving voltage ELVDD supplied to the driving voltage line PL through the driving voltage supply wiring 36.

The first transistor T1 may be connected to the driving voltage line PL and the storage capacitor Cst, and may control driving current flowing from the driving voltage line PL to the main light-emitting diode LEDm in response to a value of the voltage stored in the storage capacitor Cst.

The main light-emitting diode LEDm may be connected to the driving voltage supply wiring 36 through the first transistor T1 and the driving voltage line PL to receive the driving voltage ELVDD, and may be connected to the common voltage supply wiring 37 to receive the common voltage ELVSS. The main light-emitting diode LEDm may emit light through the flow of current due to a difference between the driving voltage ELVDD and the common voltage ELVSS.

The number of thin-film transistors and storage capacitors and a circuit design of the pixel circuit PC are not limited to those of FIG. 11, and may be modified in various ways.

Referring to FIGS. 9 to 11 together, the main pixel Pxm may perform active matrix driving, and the auxiliary pixel Pxa may perform passive matrix driving.

The main pixel Pxm may include the pixel circuit PC, and the pixel circuit PC may receive the data signal Ds and the scan signal Ss from the main data line DLm and the main scan line SLm. The pixel circuit PC may transmit the driving voltage ELVDD to the main light-emitting diode LEDm based on the data signal Ds and the scan signal Ss. The main light-emitting diode LEDm may be connected to the common voltage supply wiring 37 to receive the common voltage ELVSS. The main light-emitting diode LEDm may include an emission layer, and the emission layer may emit light according to a difference between the driving voltage LEVDD received through the pixel circuit PC and the common voltage ELVSS received through the common voltage supply wiring 37. Accordingly, the main light-emitting diode LEDm may emit light under the control of the assigned pixel circuit PC.

The auxiliary pixel Pxa may not include the pixel circuit PC, and may be directly connected to the driver DRV through the auxiliary data line DLa and the auxiliary scan line SLa. For example, the auxiliary pixel Pxa may be connected to the data driver 31 through the auxiliary data line DLa, and may be connected to the scan driver 32 through the auxiliary scan line SL. The auxiliary light-emitting diode LEDa may include two electrodes and an emission layer located between the two electrodes, and one of the two electrodes may be connected to the auxiliary scan line SLa and the other may be connected to the auxiliary data line DLa. The data driver 31 and the scan driver 32 may apply different voltages to the two electrodes of the auxiliary light-emitting diode LEDa through the auxiliary data line DLa and the auxiliary scan line SLa, and the emission layer of the auxiliary light-emitting diode LEDa may emit light through a difference between the voltages. Accordingly, a pixel circuit or a thin-film transistor may not be located in the component area CA.

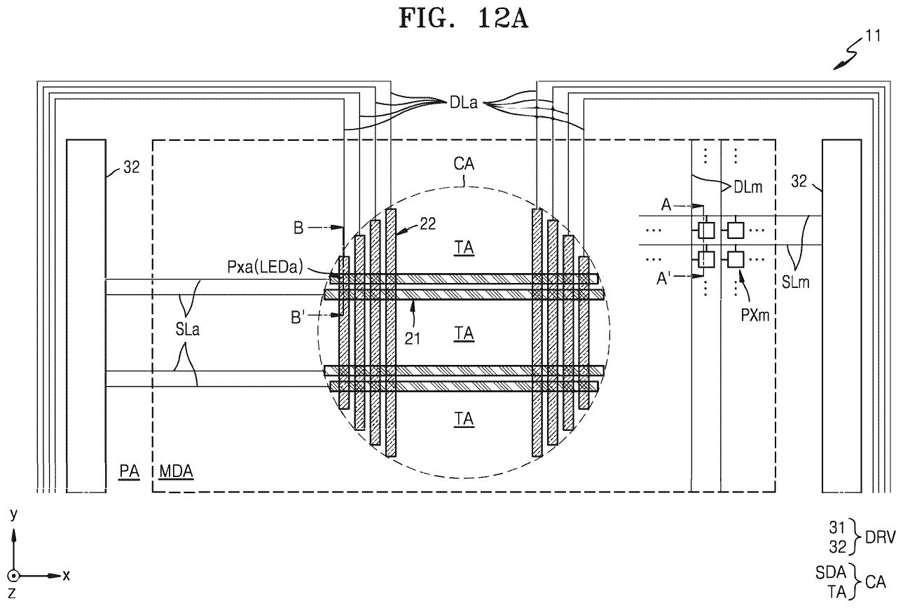

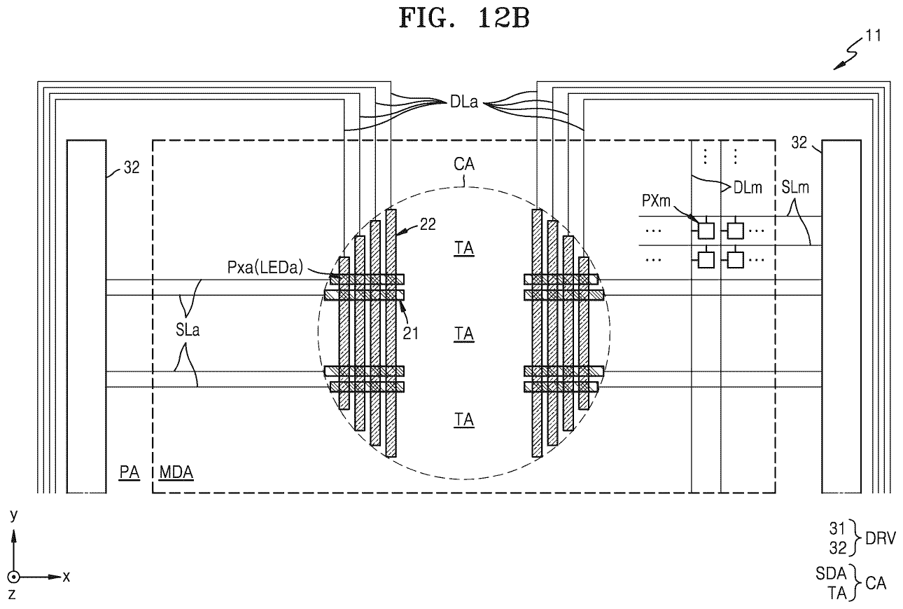

FIG. 12A is an enlarged plan view illustrating a portion of the display panel 11, according to some embodiments. FIG. 12B is an enlarged plan view illustrating a portion of the display panel 11, according to some embodiments.

Referring to FIGS. 12A and 12B, a plurality of main pixels Pxm, and a plurality of main scan lines SLm and a plurality of main data lines DLm connected to the plurality of main pixels Pxm may be located in the main display area MDA.

A plurality of first electrodes 21 and a plurality of second electrodes 22 may be located in the component area CA. The plurality of first electrodes 21 may extend along the x direction and may be arranged along the y direction. The plurality of first electrodes 21 may be spaced apart from each other. The plurality of second electrodes 22 may extend along the y direction and may be arranged along the x direction. The plurality of second electrodes 22 may be spaced apart from each other. The plurality of first electrodes 21 and the plurality of second electrodes 22 may intersect each other. There may be a plurality of areas where the plurality of first electrodes 21 and the plurality of second electrodes 22 intersect each other. As described below, the plurality of first electrodes 21 may be located on the plurality of second electrodes 22. An area where the plurality of first electrodes 21 and the plurality of second electrodes 22 are not located may be the transmissive area TA.

A plurality of auxiliary pixels Pxa may be located in the areas where the plurality of first electrodes 21 and the plurality of second electrodes 212 intersect each other. For example, a plurality of auxiliary light-emitting diodes LEDa may be located in the areas where the plurality of first electrodes 21 and the plurality of second electrodes 22 intersect each other. In other words, the auxiliary light-emitting diode LEDa may be located in areas where the first electrode 21 and the second electrode 22 overlap each other. Accordingly, the auxiliary light-emitting diode LEDa may simultaneously overlap the first electrode 21 and the second electrode 22.

A plurality of auxiliary scan lines SLa may connect the plurality of first electrodes 21 to the scan driver 32. In other words, the plurality of first electrodes 21 may be connected to the scan driver 32 through the plurality of auxiliary scan lines SLa. One auxiliary scan line SLa may be connected to one first electrode 21.

According to some embodiments, as shown in FIG. 12A, the plurality of first electrodes 21 may extend across the entire component area CA, and may be connected to the plurality of auxiliary scan lines SLa and the scan driver 32 arranged in the −x direction of the component area CA. According to some embodiments, the plurality of first electrodes 21 may be connected to the plurality of auxiliary scan lines SLa and the scan driver 32 arranged in the +x direction of the component area CA. According to some embodiments, some of the plurality of first electrodes 21 arranged along the y direction may be connected to the plurality of auxiliary scan lines SLa and the scan driver 32 arranged in the −x direction of the component area CA, and the others may be connected to the plurality of auxiliary scan lines SLa and the scan driver 32 arranged in the +x direction of the component area CA.

According to some embodiments, as shown in FIG. 12B, the first electrode 21 may extend partially across the component area CA. Some of the plurality of first electrodes 21 may be connected to the plurality of auxiliary scan lines SLa and the scan driver 32 arranged in the −x direction of the component area CA, and the others may be connected to the plurality of auxiliary scan lines SLa and the scan driver 32 arranged in the +x direction of the component area CA.

According to some embodiments, the first component 21 may be connected to the auxiliary scan line SLa at a boundary between the main display area MDA and the component area CA. According to some embodiments, the first electrode 21 may be connected to the auxiliary scan line SLa in a part of the main display area MDA adjacent to the component area CA. According to some embodiments, the first electrode 21 may be connected to the auxiliary scan line SLa in a part of the component area CA adjacent to the main display area MDA.

A plurality of auxiliary data lines DLa may connect the plurality of second electrodes 22 to the data driver 31. In other words, the plurality of second electrodes 22 may be connected to the data driver 31 through the plurality of auxiliary data lines DLa. One auxiliary data line DLa may be connected to one second electrode 22.

According to some embodiments, the second electrode 22 may be connected to the auxiliary data line DLa at a boundary between the main display area MDA and the component area CA. According to some embodiments, the second electrode 22 may be connected to the auxiliary data line DLa in a part of the main display area MDA adjacent to the component area CA. According to some embodiments, the second electrode 22 may be connected to the auxiliary data line DLa in a part of the component area CA adjacent to the main display area MDA.

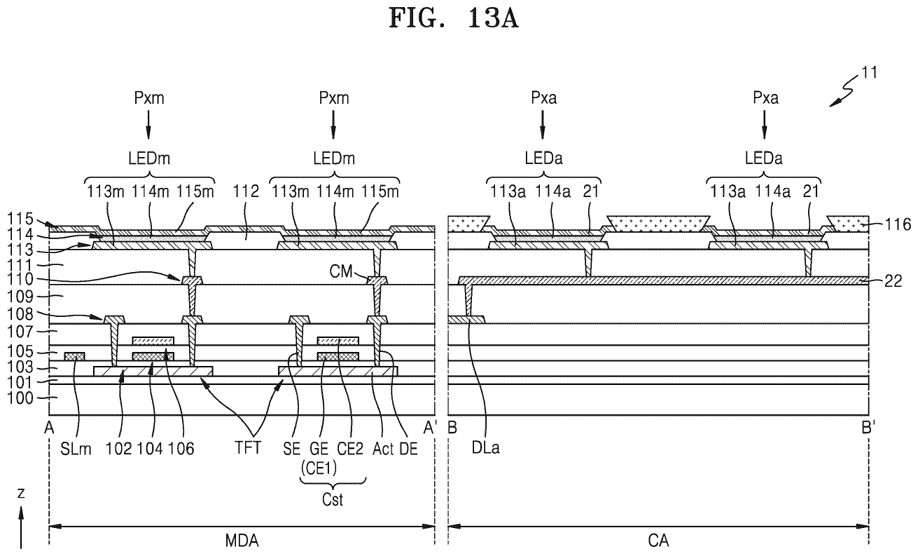

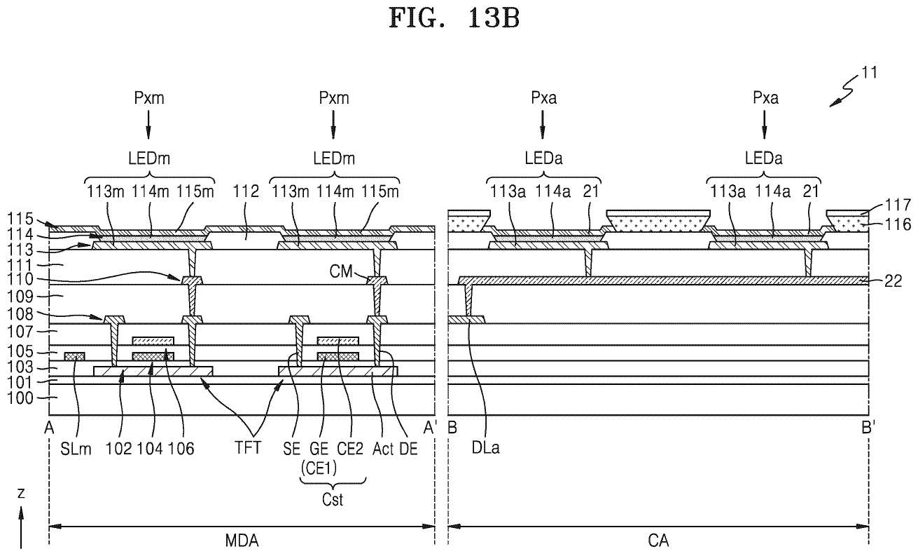

According to some embodiments, the plurality of second electrodes 22 may be patterned into a shape as described above. According to some embodiments, the plurality of first electrodes 21 may be formed to have a shape as described above through a process described with reference to FIGS. 13A to 17.

FIG. 13A is a cross-sectional view illustrating the display panel 11, according to some embodiments. FIG. 13B is a cross-sectional view illustrating the display panel 11, according to some embodiments. FIGS. 13A and 13B are cross-sectional views illustrating the display panel 11 taken along the lines A-A′ and B-B′ of FIG. 12A.

Referring to FIG. 13A, a plurality of main pixels Pxm and a plurality of auxiliary pixels Pxa may be located on the substrate 100. The main pixel Pxm may include the main light-emitting diode LEDm, a thin-film transistor TFT, and the storage capacitor Cst. According to some embodiments, the thin-film transistor TFT of the main pixel Pxm may be the first transistor T1 described with reference to FIG. 11. The auxiliary pixel Pxa may include the auxiliary light-emitting diode LEDa.

A first insulating layer 101 may be located on the substrate 100. The first insulating layer 101 may entirely cover the substrate 100. The first insulating layer 101 may planarize and protect a top surface of the substrate 100. The first insulating layer 101 may include an inorganic insulating material. According to some embodiments, the first insulating layer 101 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may have a single or multi-layer structure. According to some embodiments, the first insulating layer 101 may be a buffer layer.

The thin-film transistor TFT may be located on the first insulating layer 101. The thin-film transistor TFT may include an active layer ACT, a gate electrode GE, a source electrode SE, and a drain electrode DE. The thin-film transistor TFT corresponding to each main pixel Pxm may be provided on the first insulating layer 101.

A semiconductor layer 102 may be located on the first insulating layer 101. The semiconductor layer 102 may include the active layer ACT. The active layer ACT may be patterned to correspond to each thin-film transistor TFT. The active layer ACT may include a drain region overlapping the drain electrode DE, a source region overlapping the source electrode SE, and a channel region between the drain region and the source region. The drain region and the source region may be regions doped with impurities (i.e., dopants).

A second insulating layer 103 may be located on the semiconductor layer 102. The second insulating layer 103 may include an inorganic insulating material. According to some embodiments, the second insulating layer 103 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may have a single or multi-layer structure. According to some embodiments, the second insulating layer 103 may be a first gate insulating layer. According to some embodiments, as shown in FIG. 4, the second insulating layer 103 may entirely cover the semiconductor layer 102 and the first insulating layer 101. According to some embodiments, the second insulating layer 103 may be patterned to cover only each active layer ACT and not to cover a top surface of the first insulating layer 101 between the active layers ACT. According to some embodiments, the second insulating layer 103 may be patterned to cover only a portion of each active layer ACT (e.g., a portion, that is, the channel region, overlapping the gate electrode GE).

The storage capacitor Cst may be located on the second insulating layer 103. The storage capacitor Cst may include a first capacitor electrode CE1 and a second capacitor electrode CE2. The second capacitor electrode CE2 may be located on the first capacitor electrode CE1.

A first conductive layer 104 may be located on the second insulating layer 103. The first conductive layer 104 may include the gate electrode GE and the first capacitor electrode CE1. The gate electrode GE may be patterned to correspond to each thin-film transistor TFT. The gate electrode GE may overlap the channel region of the active layer ACT. The first capacitor electrode CE1 may be patterned to correspond to each storage capacitor Cst. According to some embodiments, the gate electrode GE and the first capacitor electrode CE1 may be integrally provided as shown in FIG. 13A. According to some embodiments, the gate electrode GE and the first capacitor electrode CE1 may be individually provided. According to some embodiments, the first conductive layer 104 may include the main scan line SLm. According to some embodiments, the first conductive layer 104 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may have a single or multi-layer structure.

A third insulating layer 105 may be located on the first conductive layer 104. The third insulating layer 105 may entirely cover the first conductive layer 104. The third insulating layer 105 may include an inorganic insulating material. According to some embodiments, the third insulating layer 105 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may have a single or multi-layer structure. According to some embodiments, the third insulating layer 105 may be a second gate insulating layer.

A second conductive layer 106 may be located on the third insulating layer 105. The second conductive layer 106 may include the second capacitor electrode CE2 of each storage capacitor Cst. The second capacitor electrode CE2 may be patterned to correspond to each storage capacitor Cst. The second capacitor electrode CE2 may overlap the first capacitor electrode CE1. According to some embodiments, the second conductive layer 106 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may have a single or multi-layer structure.

A fourth insulating layer 107 may be located on the second conductive layer 106. The fourth insulating layer 107 may entirely cover the second conductive layer 106. The fourth insulating layer 107 may include an inorganic insulating material. According to some embodiments, the fourth insulating layer 107 may include at least one inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂), and may have a single or multi-layer structure. According to some embodiments, the fourth insulating layer 107 may be an interlayer insulating layer.

A third conductive layer 108 may be located on the fourth insulating layer 107. The third conductive layer 108 may include the source electrode SE and the drain electrode DE of each thin-film transistor TFT. The source electrode SE and the drain electrode DE may be patterned to correspond to each TFT. The source electrode SE may overlap the source region of the active layer ACT. The drain electrode DE may overlap the drain region of the active layer ACT. The source electrode SE may be connected to the active layer ACT (e.g., the source region of the active layer ACT) through an opening defined in the second to fourth insulating layers 103, 105, and 107. The drain electrode DE may be connected to the active layer ACT (e.g., the drain region of the active layer ACT) through an opening defined in the second to fourth insulating layers 103, 105, and 107. According to some embodiments, the third conductive layer 108 may include a main data line. According to some embodiments, the third conductive layer 108 may include the auxiliary data line DLa. According to some embodiments, the third conductive layer 108 may include at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may have a single or multi-layer structure.

A fifth insulating layer 109 may be located on the third conductive layer 108. An opening overlapping the drain electrode DE may be defined in the fifth insulating layer 109. The fifth insulating layer 109 may include an organic insulating material. According to some embodiments, the fifth insulating layer 109 may include an organic insulating material such as benzocyclobutene, polyimide, hexamethyldisiloxane, a general-purpose polymer such as polymethylmethacrylate or polystyrene, a polymer derivative having a phenol-based group, an acrylic polymer, an imide-based polymer, an aryl ether-based polymer, an amide-based polymer, a fluorine-based polymer, a p-xylene-based polymer, or a vinyl alcohol-based polymer, and may have a single or multi-layer structure. According to some embodiments, the fifth insulating layer 109 may be a first via layer.

A fourth conductive layer 110 may be located on the fifth insulating layer 109. The fourth conductive layer 110 may include a contact metal CM corresponding to each main pixel Pxm. The contact metal CM may be connected to the drain electrode DE through an opening defined in the fifth insulating layer 109. The fourth conductive layer 110 may include the second electrode 22. The second electrode 22 may be connected to the auxiliary data line DLa through an opening defined in the fifth insulating layer 109.

According to some embodiments, the fourth conductive layer 110 may include a metal. For example, the fourth conductive layer 110 may include at least one metal such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may have a single or multi-layer structure.

According to some embodiments, the fourth conductive layer 110 may include a transparent conductive oxide (TCO). For example, the fourth conductive layer 110 may include at least one conductive oxide such as indium tin oxide (ITO), indium zinc oxide (IZO), zinc oxide (ZnO), indium oxide (In₂O₃), indium gallium oxide (IGO), or aluminum zinc oxide (AZO), and may have a single or multi-layer structure.

A sixth insulating layer 111 may be located on the fourth conductive layer 110. An opening overlapping the contact metal CM and at least one opening overlapping the second electrode 22 may be defined in the sixth insulating layer 111. According to some embodiments, the sixth insulating layer 111 may include an organic insulating material such as benzocyclobutene, polyimide, hexamethyldisiloxane, a general-purpose polymer such as polymethylmethacrylate or polystyrene, a polymer derivative having a phenol-based group, an acrylic polymer, an imide-based polymer, an aryl ether-based polymer, an amide-based polymer, a fluorine-based polymer, a p-xylene-based polymer, or a vinyl alcohol-based polymer, and may have a single or multi-layer structure. According to some embodiments, the sixth insulating layer 111 may be a second via layer.

The main light-emitting diode LEDm and the auxiliary light-emitting diode LEDa may be located on the sixth insulating layer 111. The main light-emitting diode LEDm may include a main pixel electrode 113m, a main intermediate layer 114m, and a counter electrode 115m. The auxiliary light-emitting diode LEDa may include an auxiliary pixel electrode 113a, an auxiliary intermediate layer 114a, and the first electrode 21. Not all of the first electrode 21 is included in the auxiliary light-emitting diode LEDa, and a part of the first electrode 21 intersecting and overlapping the second electrode 22 may be included in the auxiliary light-emitting diode LEDa. In other words, the auxiliary pixel electrode 113a may be located in an area where the first electrode 21 and the second electrode 22 intersect each other, and a part of the first electrode 21 overlapping the auxiliary pixel electrode 113a may be included in the auxiliary light-emitting diode LEDa.

A fifth conductive layer 113 may be located on the sixth insulating layer 111. The fifth conductive layer 113 may include the main pixel electrode 113m and the auxiliary pixel electrode 113a. The main pixel electrode 113m may be connected to the contact metal CM through an opening defined in the sixth insulating layer 111. The main pixel electrode 113m may be connected to the thin-film transistor TFT through the contact metal CM and the drain electrode DE. The auxiliary pixel electrode 113a may be connected to the second electrode 22 through an opening defined in the sixth insulating layer 111. The auxiliary pixel electrode 113a may be connected to the auxiliary data line DLa through the second electrode 22.

Referring to FIG. 12A together, the auxiliary pixel electrodes 113a of the auxiliary light-emitting diodes LEDa of the auxiliary pixels Pxa arranged along the y direction may be connected to the same second electrode 22.

According to some embodiments, the fifth conductive layer 113 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). According to some embodiments, the fifth conductive layer 113 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. However, a configuration and a material of the fifth conductive layer 113 are not limited thereto, and various modifications may be made.

A first bank layer 112 may be located on the fifth conductive layer 113. The first bank layer 112 may include an opening overlapping a central portion of the main pixel electrode 113m. In other words, the first bank layer 112 may cover an edge (or an edge portion) of the main pixel electrode 113m. The opening of the first bank layer 112 overlapping the central portion of the main pixel electrode 113m may define an emission area of the main light-emitting diode LEDm and the main pixel Pxm. The first bank layer 112 may include an opening overlapping a central portion of the auxiliary pixel electrode 113a. In other words, the first bank layer 112 may cover an edge (or an edge portion) of the auxiliary pixel electrode 113a. The opening of the first bank layer 112 overlapping the central portion of the auxiliary pixel electrode 113a may define an emission area of the auxiliary light-emitting diode LEDa and the auxiliary pixel Pxa.

An intermediate layer 114 may be located on the fifth conductive layer 113. The intermediate layer 114 may include the main intermediate layer 114m overlapping the main pixel electrode 113m, and the auxiliary intermediate layer 114a overlapping the auxiliary pixel electrode 113a. According to some embodiments, the intermediate layer 114 may include the emission layer and a functional layer. The emission layer may include a low molecular weight material or a high molecular weight material that emits light when a certain voltage is applied (or when certain current flows). The functional layer may include at least one of an electron transport layer (ETL), an electron injection layer (EIL), a hole transport layer (HTL), or a hole injection layer (HIL). According to some embodiments, the main intermediate layers 114m of adjacent main light-emitting diodes LEDm may include different materials. Accordingly, adjacent main light-emitting diodes LEDm may emit light of different colors. According to some embodiments, the auxiliary intermediate layers 114a of adjacent auxiliary light-emitting diodes LEDa may include different materials. Accordingly, adjacent auxiliary light-emitting diodes LEDa may emit light of different colors.

A second bank layer 116 may be located on the first bank layer 112. The second bank layer 116 may be located in the component area CA. The second bank layer 116 may have a reverse tapered structure in which an upper width is greater than a lower width. For example, an upper portion of the second bank layer 116 may protrude toward an opening of the first bank layer 112 more than a lower portion of the second bank layer 116. According to some embodiments, a width of a bottom surface of the second bank layer 116 may be less than a width of a top surface of the first bank layer 112. According to some embodiments, a width of a top surface of the second bank layer 116 may be greater than a width of a top surface of the first bank layer 112.

A sixth conductive layer 115 may be located on the first bank layer 112. The sixth conductive layer 115 may include the counter electrode 115m and a plurality of first electrodes 21. According to some embodiments, the counter electrode 115m may be integrally provided over the entire main display area MDA. In this case, a part of the counter electrode 115m overlapping each main pixel electrode 113m or each main intermediate layer 114 may be the counter electrode 115m of each main light-emitting diode LEDm. Alternatively, each main light-emitting diode LEDm may include a part of the counter electrode 115m overlapping the corresponding main pixel electrode 113m or main intermediate layer 114m.

The first electrode 21 may overlap the corresponding auxiliary pixel electrode 113a and auxiliary intermediate layer 114a. The plurality of first electrodes 21 may be spaced apart from each other with the second bank layer 116 therebetween. According to some embodiments, a part of the first electrode 21 may be located on a top surface of the first bank layer 112 and may partially cover the top surface of the first bank layer 112. According to some embodiments, the first electrode 21 may not be located on a top surface of the second bank layer 116.

According to some embodiments, the plurality of first electrodes 21 may be formed through the following process. First, the sixth conductive layer 115 may be arranged over the entire main display area MDA and component area CA. The sixth conductive layer 115 may be integrally arranged in the main display area MDA. In the component area CA, a first portion of the sixth conductive layer 115 may be located on the top surface of the second bank layer 116 and a second portion of the sixth conductive layer 115 may be located on the auxiliary intermediate layer 114a, and the first portion and the second portion may be disconnected from each other by the reverse tapered structure of the second bank layer 116. A part of the sixth conductive layer 115 located on the auxiliary intermediate layer 114a may be the first electrode 21. Through a subsequent process, for example, a laser processing process, a part of the sixth conductive layer 115 located on the second bank layer 116 may be removed. Accordingly, in FIG. 13A, the sixth conductive layer 115 is not located on the second bank layer 116.

The sixth conductive layer 115 may include a conductive material having a low work function. For example, the sixth conductive layer 115 may include a transparent layer (or a semi-transparent layer) including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. Alternatively, the sixth conductive layer 115 may further include a layer including a material such as indium tin oxide (ITO), indium zinc oxide (IZO), zinc oxide (ZnO), or indium oxide (In₂O₃) on the transparent layer (or the semi-transparent layer) including the above material.

Referring to FIG. 13B, an anti-adhesive layer 117 may be located on the second bank layer 116.

According to some embodiments, the plurality of second electrodes 21 may be formed through the following process. First, the sixth conductive layer 115 may be arranged over the entire main display area MDA and component area CA. The sixth conductive layer 115 may be integrally arranged in the main display area MDA. In the component area CA, a part of the sixth conductive layer 115 may be located on the auxiliary intermediate layer 114a. A part of the sixth conductive layer 115 located on the auxiliary intermediate layer 114a may be the first electrode 21. The anti-adhesive layer 117 may prevent the sixth conductive layer 115 from being located on a top surface of the second bank layer 116 or a top surface of the anti-adhesive layer 117. Accordingly, in FIG. 13B, the sixth conductive layer 115 is not located on the second bank layer 116 or the anti-adhesive layer 117. The embodiments of FIG. 13A may be implemented by removing the anti-adhesive layer 117 through a subsequent process.

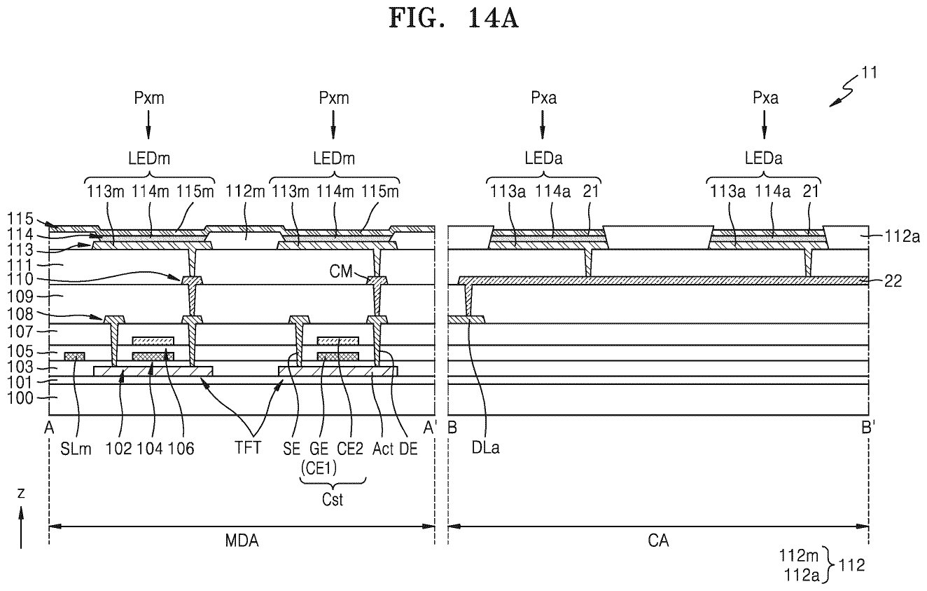

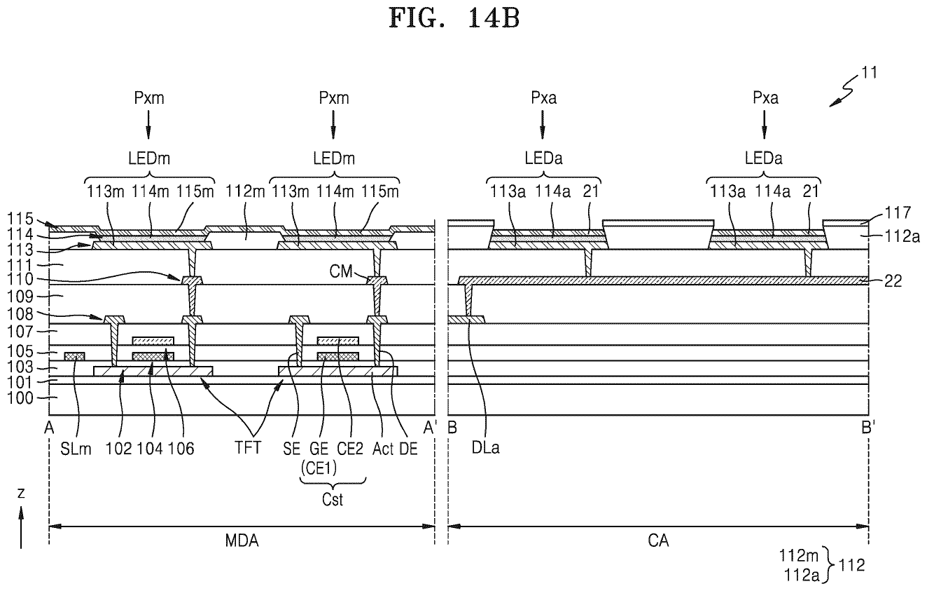

FIG. 14A is a cross-sectional view illustrating the display panel 11, according to some embodiments. FIG. 14B is a cross-sectional view illustrating the display panel 11, according to some embodiments. FIGS. 14A and 14B may be cross-sectional views illustrating the display panel 11 taken along the lines A-A′ and B-B′ of FIG. 12A. Hereinafter, the same features of the embodiments of FIGS. 14A and 14B as those of the embodiments of FIG. 13A or 13B will not be repeatedly described.

Referring to FIG. 14A, a shape of the first bank layer 112 may be different in the main display area MDA and the component area CA. According to some embodiments, the first bank layer 112 may include a 1-1 bank layer 112m located in the main display area MDA and a 1-2 bank layer 112a located in the component area CA.

Features of the 1-1 bank layer 112m may be substantially the same as those of the first bank layer 112 described with reference to FIG. 13A.

The 1-2 bank layer 112a may have a thickness greater than that of the 1-1 bank layer 112m. According to some embodiments, the 1-2 bank layer 112a may have a reverse tapered structure, like the second bank layer 116 of FIG. 13A. According to some embodiments, a top surface of the 1-2 bank layer 112a may be located higher (e.g., in a +z direction) than a top surface of the sixth conductive layer 115.

The 1-2 bank layer 112a may include an opening, and the auxiliary pixel electrode 113a, the auxiliary intermediate layer 114a, and the first electrode 21 may be located in the opening of the 1-2 bank layer 112a. Accordingly, the 1-2 bank layer 112a may define an emission area of the auxiliary light-emitting diode LEDa and the auxiliary pixel Pxa. A plurality of first electrodes 21 may be spaced apart from each other with the 1-2 bank layer 112a therebetween.

According to some embodiments, the plurality of first electrodes 21 may be formed through the following process. First, the sixth conductive layer 115 may be arranged over the entire main display area MDA and component area CA. The sixth conductive layer 115 may be integrally arranged in the main display area MDA. Accordingly, the sixth conductive layer 115 may cover the 1-1 bank layer 112m. In the component area CA, a first portion of the sixth conductive layer 115 may be located on the top surface of the 1-2 bank layer 112a and a second portion of the sixth conductive layer 115 may be located on the auxiliary intermediate layer 114a, and the first portion and the second portion may be disconnected from each other by the reverse tapered structure of the 1-2 bank layer 112a. A part of the sixth conductive layer 115 located on the auxiliary intermediate layer 114a may be the first electrode 21. Through a subsequent process, for example, a laser processing process, a part of the sixth conductive layer 115 located on the 1-2 bank layer 112a may be removed. Accordingly, in FIG. 14A, the sixth conductive layer 115 is not located on the 1-2 bank layer 112a.

Referring to FIG. 14B, the anti-adhesive layer 117 may be located on the 1-2 bank layer 112a.

According to some embodiments, the plurality of first electrodes 21 may be formed through the following process. First, the sixth conductive layer 115 may be arranged over the entire main display area MDA and component area CA. The sixth conductive layer 115 may be integrally arranged in the main display area MDA. In the component area CA, a part of the sixth conductive layer 115 may be located on the auxiliary intermediate layer 114a. A part of the sixth conductive layer 115 located on the auxiliary intermediate layer 114a may be the first electrode 21. The anti-adhesive layer 117 may prevent the sixth conductive layer 115 from being located on a top surface of the 1-2 bank layer 112 or a top surface of the anti-adhesive layer 117. Accordingly, in FIG. 14B, the sixth conductive layer 115 is not located on the 1-2 bank layer 112a or the anti-adhesive layer 117. The embodiments of FIG. 14A may be implemented by removing the anti-adhesive layer 117 through a subsequent process.

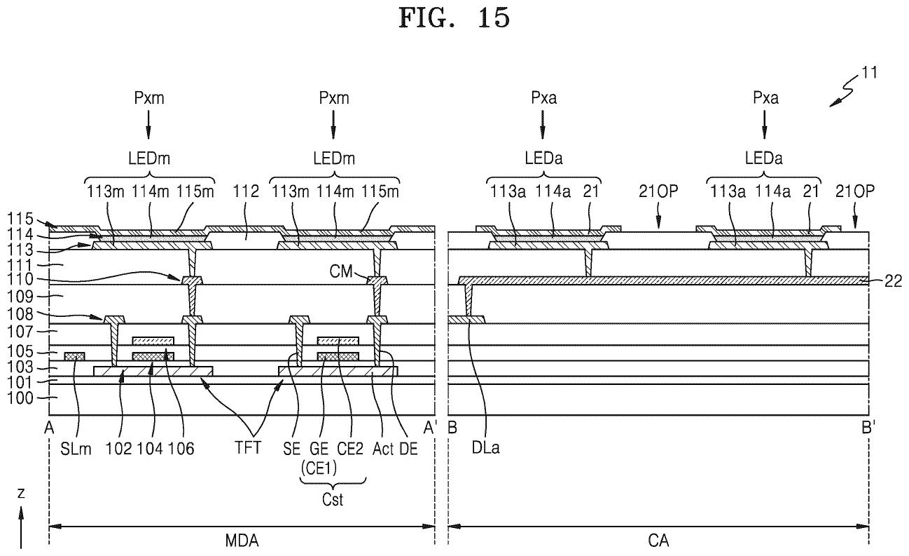

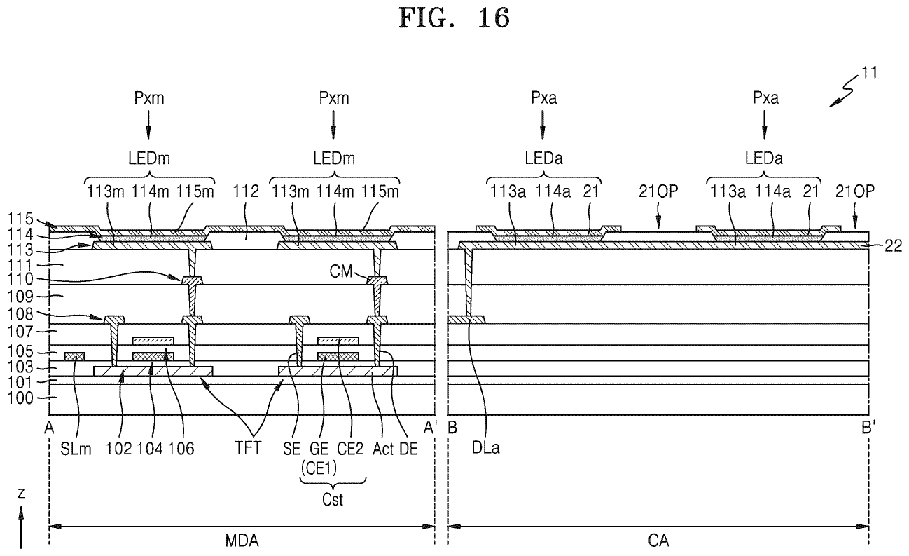

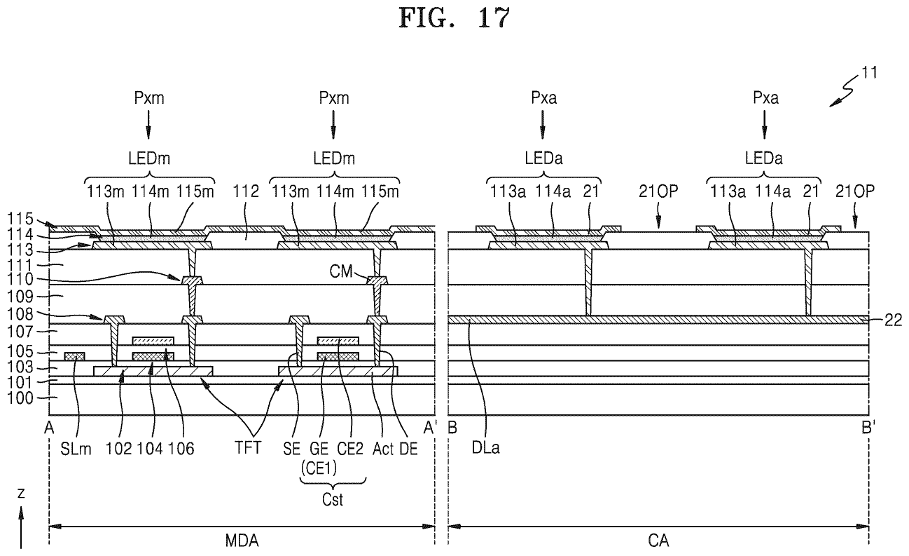

FIG. 15 is a cross-sectional view illustrating the display panel 11, according to some embodiments. FIG. 16 is a cross-sectional view illustrating the display panel 11, according to some embodiments. FIG. 17 is a cross-sectional view illustrating the display panel 11, according to some embodiments. FIGS. 15 to 17 may be cross-sectional views illustrating the display panel 11 taken along the lines A-A′ and B-B′ of FIG. 12A. Hereinafter, the same features of the embodiments of FIGS. 15 to 17 as those of the embodiments of FIG. 13A or 13B will not be repeatedly described.

Referring to FIGS. 15 to 17, the sixth conductive layer 115 may be integrally located in the main display area MDA, and may be separated into a plurality of first electrodes 21 in the component area CA. The plurality of first electrodes 21 may be spaced apart from each other. The sixth conductive layer 115 may include an opening 21OP located between adjacent first electrodes 21. In other words, adjacent first electrodes 21 may be spaced apart from each other with the opening 21OP of the sixth conductive layer 115 therebetween. A part of the first bank layer 112 may be exposed through the opening 21OP of the sixth conductive layer 115. The first electrode 21 may cover an edge portion of the first bank layer 112.

According to some embodiments, the plurality of first electrodes 21 may be formed through the following process. First, the sixth conductive layer 115 may be located over the entire main display area MDA and component area CA. The sixth conductive layer 115 may be integrally arranged in the main display area MDA. Through a subsequent process, for example, a laser processing process, a part of the sixth conductive layer 115 overlapping the first bank layer 112 in the component area CA may be removed. Another part of the sixth conductive layer 115 remaining in the component area CA after a part of the sixth conductive layer 115 is removed may be the plurality of first electrodes 21. In other words, the first electrode 21 may be patterned through a laser processing process. According to some embodiments, the sixth conductive layer 115 may be removed even at a boundary between the component area CA and the main display area MDA.

Referring to FIG. 16, the fifth conductive layer 113 may include the second electrode 22. In other words, the second electrode 22 may be integrally formed with the auxiliary pixel electrodes 113a.

According to some embodiments, one second electrode 22 may intersect and overlap a plurality of first electrodes 21. The auxiliary intermediate layer 114a may be located between the first electrode 21 and the second electrode 22 in an area where the first electrode 21 and the second electrode 22 overlap each other. In this case, a part of the second electrode 22 on which the auxiliary intermediate layer 114a is located while overlapping the first electrode 21 may be the auxiliary pixel electrode 113a. According to some embodiments, the second electrode 22 may be connected to the auxiliary data line DLa through an opening defined in the fifth insulating layer 109 and the sixth insulating layer 111.

Referring to FIG. 17, the third conductive layer 108 may include the second electrode 22. In other words, the second electrode 22 may be integrally formed with the auxiliary data line DLa. According to some embodiments, the auxiliary pixel electrode 113a may be connected to the second electrode 22 and the auxiliary data line DLa through an opening defined in the fifth insulating layer 109 and the sixth insulating layer 111.

A structure of the first bank layer 112, the second bank layer 116, and/or the anti-adhesive layer 117 described with reference to FIGS. 13A to 14B and an arrangement of the second electrode 22 described with reference to FIGS. 15 to 17 may be combined in various ways, and these combinations also fall within the scope of the disclosure.

According to some embodiments, the display panel 11 may further include the encapsulation layer 300 (see FIG. 8) covering the main light-emitting diode LEDm and the auxiliary light-emitting diode LEDa.

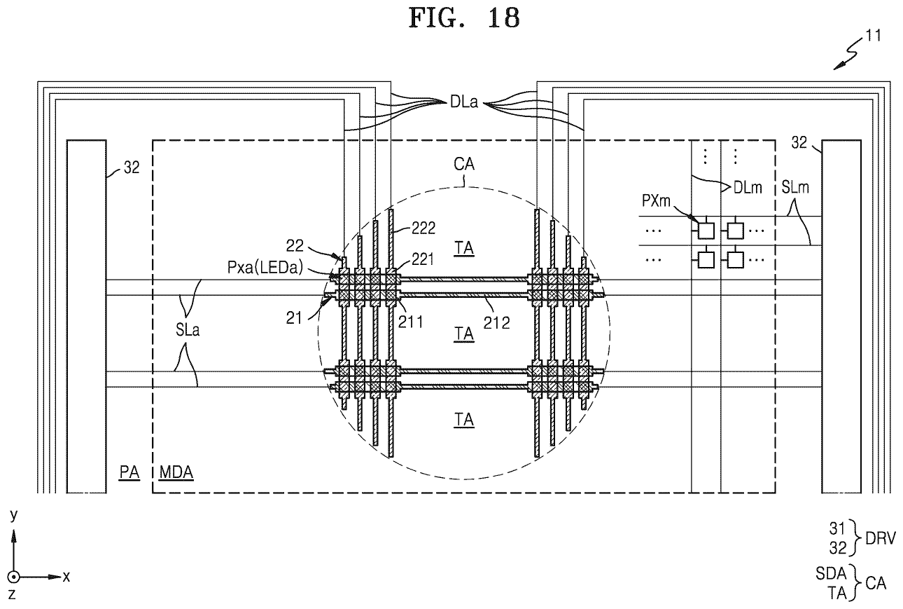

FIG. 18 is an enlarged plan view illustrating a portion of the display panel 11, according to some embodiments.

Referring to FIG. 18, a width of the first electrode 21 and a width of the second electrode 22 may be different according to a position.

In the disclosure, a width of the first electrode 21 (e.g., a width of a first portion 211 of the first electrode 21 or a width of a second portion 212 of the first electrode 21) refers to a dimension of the first electrode 21 measured along a direction (i.e., the y direction) intersecting a direction (i.e., the x direction) in which the first electrode 21 extends. In the disclosure, a width of the second electrode 22 (e.g., a width of a first portion 221 of the second electrode 22 or a width of a second portion 222 of the second electrode 22) refers to a dimension of the second electrode 22 measured along a direction (i.e., the x direction) intersecting a direction (i.e., the y direction) in which the second electrode 22 extends.

The first electrode 21 may include the first portion 211 intersecting and overlapping a plurality of second electrodes 22. A remaining portion of the first electrode 21 other than the first portion 211 of the first electrode 21 may be defined as the second portion 212 of the first electrode 21. A width of the first portion 211 of the first electrode 21 may be greater than a width of the second portion 212 of the first electrode 21.

The second electrode 22 may include the first portion 221 intersecting and overlapping a plurality of first electrodes 21. A remaining portion of the second electrode 22 other than the first portion 221 of the second electrode 22 may be defined as the second portion 222 of the second electrode 22. A width of the first portion 221 of the second electrode 22 may be greater than a width of the second portion 222 of the second electrode 22.

In the plurality of first electrodes 21 and the plurality of second electrodes, because the first portions 211 and 221 intersecting each other have sufficient dimensions, an area where the auxiliary pixel Pxa may be located may be guaranteed. At the same time, in the plurality of first electrodes 21 and the plurality of second electrodes 22, because the second portions 212 and 222 where the auxiliary pixel Pxa is not located have relatively small widths, an area where the plurality of first electrodes 21 and the plurality of second electrodes 22 are located may be relatively reduced. Because the area where the plurality of first electrodes 21 and the plurality of second electrodes 22 are located is relatively reduced, the area of the transmissive area TA may be relatively increased. Accordingly, a transmittance of the component area CA may be relatively improved.

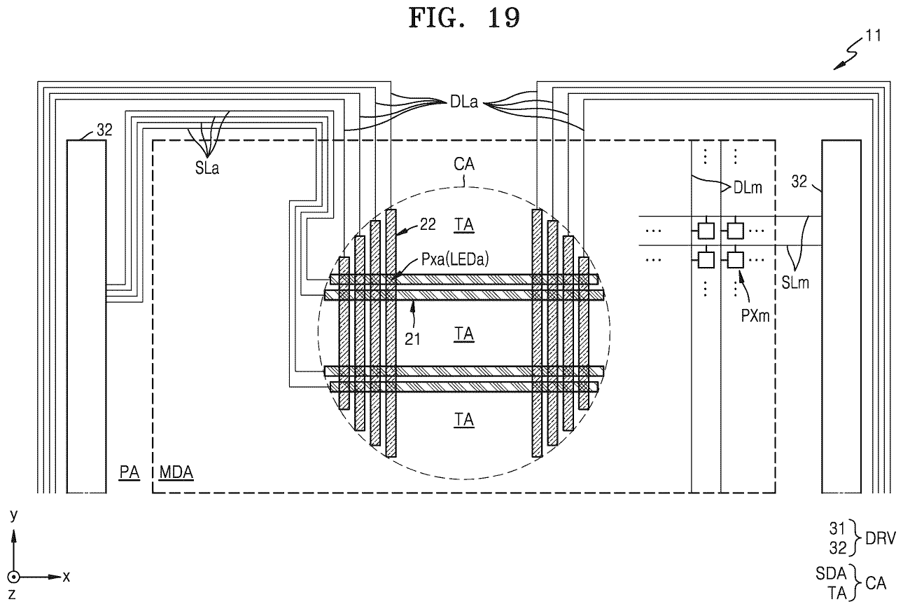

FIG. 19 is an enlarged plan view illustrating a portion of the display panel 11, according to some embodiments.

Referring to FIG. 19, at least some of the auxiliary scan lines SLa may bypass without crossing the main display area MDA. For example, at least some of the auxiliary scan lines SLa may extend along a circumference of the main display area MDA.

According to some embodiments, the auxiliary scan lines SLa may extend toward the peripheral area PA along the y direction. The auxiliary scan lines SLa may be bent in the peripheral area PA, may extend along a boundary between the main display area MDA and the peripheral area PA, and may be connected to the scan driver 32.

FIG. 19 illustrates embodiments in which the auxiliary scan lines SLa extend in the x direction along a boundary between the main display area MDA and the peripheral area PA, are bent at a corner of the main display area MDA, extend in the y direction, are bent again, and are connected to the scan driver 32. Because the auxiliary scan lines SLa are arranged by bypassing the main display area MDA, an area where the main scan lines SLm are to be located may be sufficiently secured, and a case where the auxiliary scan lines SLa affect driving of the main pixel Pxm may be prevented (or at least reduced). However, the disclosure is not limited to a specific arrangement of the auxiliary scan lines SLa as shown in FIG. 19.

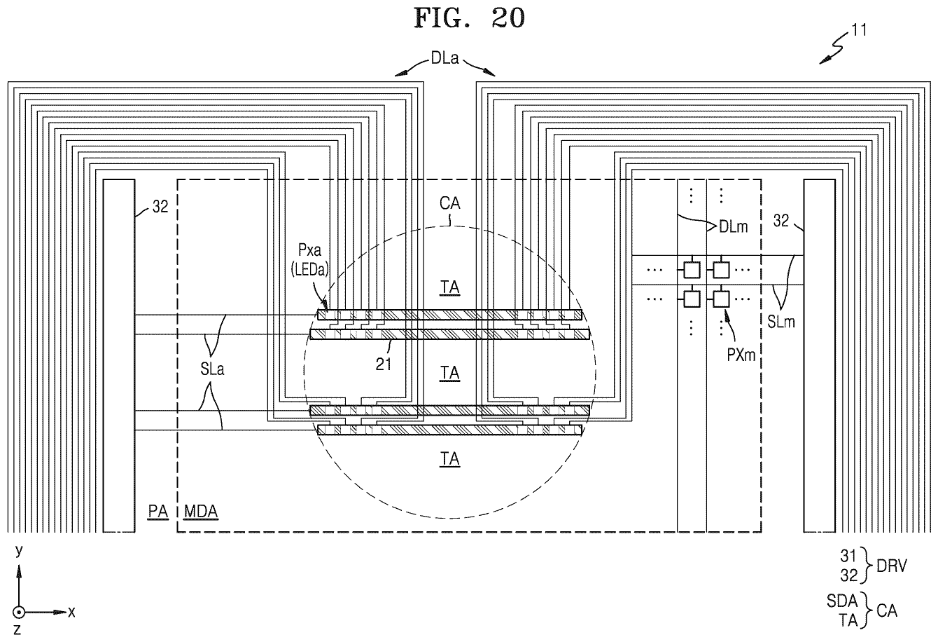

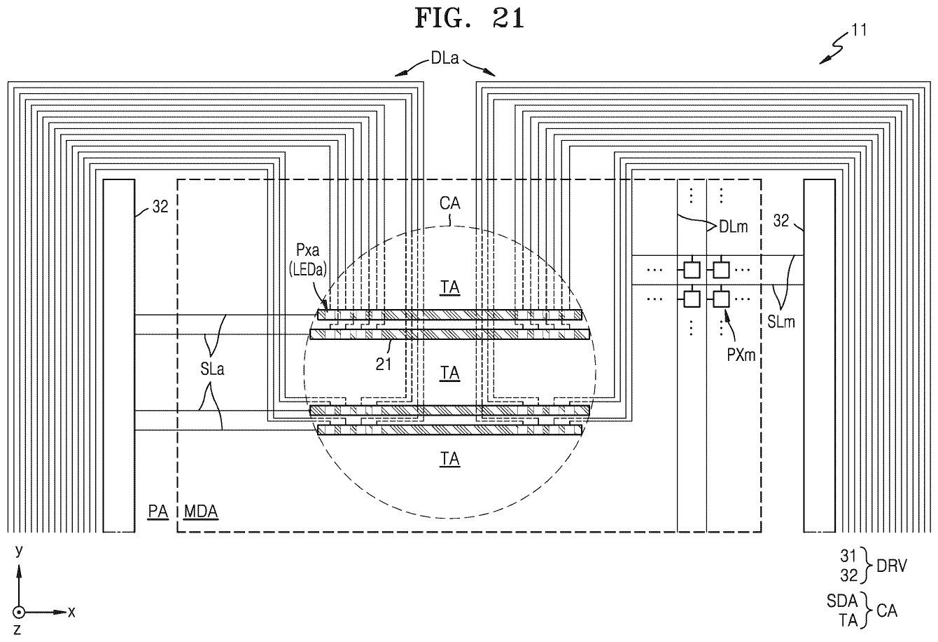

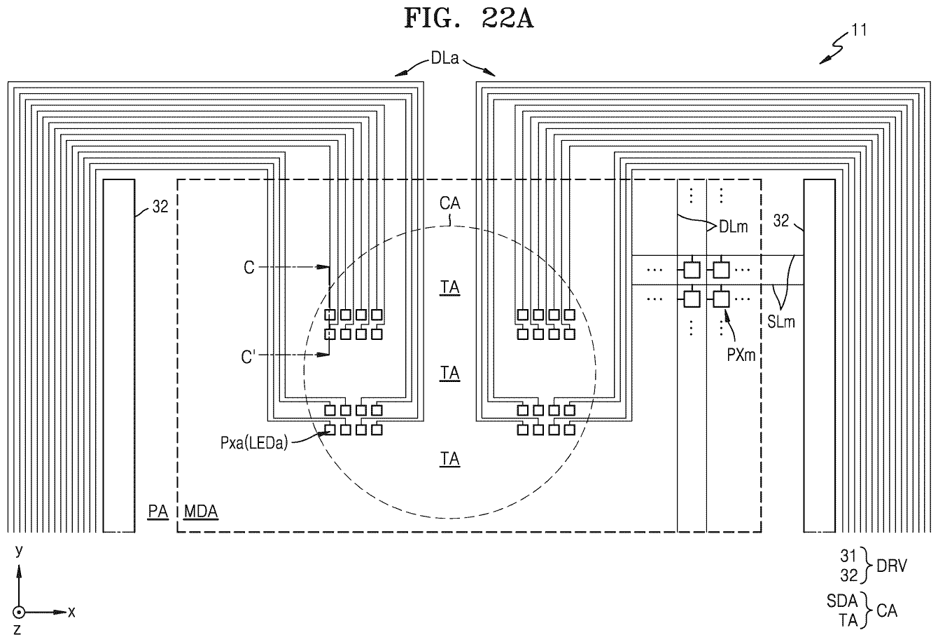

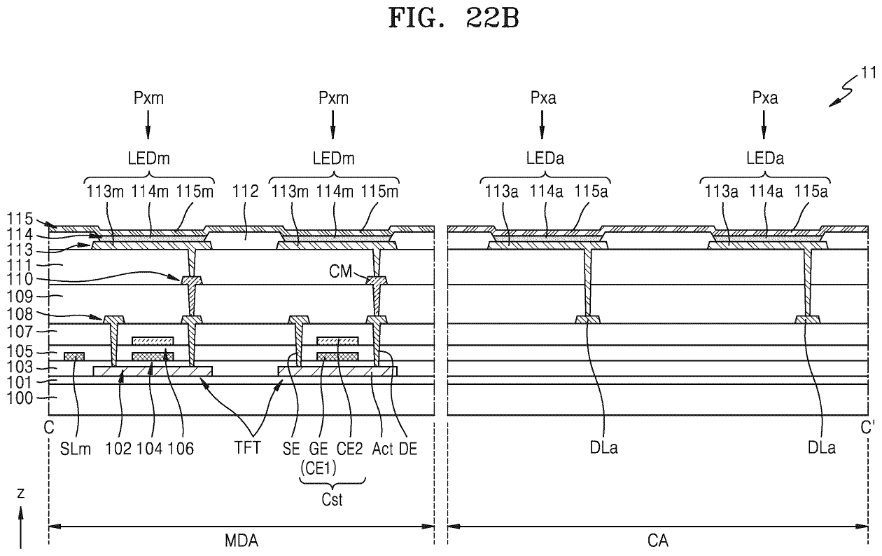

FIG. 20 is an enlarged plan view illustrating a portion of the display panel 11, according to some embodiments. FIG. 21 is an enlarged plan view illustrating a portion of the display panel 11, according to some embodiments. FIG. 22A is an enlarged plan view illustrating a portion of the display panel 11, according to some embodiments. FIG. 22B is a cross-sectional view illustrating the display panel 11 taken along the line C-C′ of FIG. 22A.

Referring to FIGS. 20 and 21, the auxiliary pixels Pxa or the auxiliary light-emitting diodes LEDa may be individually connected to the data driver 31.

Referring to FIG. 12A together as an example for comparison, the auxiliary pixels Pxa (or the auxiliary light-emitting diodes LEDa) arranged along the y direction in the embodiments of FIG. 12A may be connected together to the same second electrode 22 and may be connected to the data driver 31 through one auxiliary data line DLa.

However, in the embodiments of FIGS. 20 and 21, the display panel 11 may not include the second electrode 22. Accordingly, the auxiliary data line DLa may be individually connected to each auxiliary pixel Pxa (or the auxiliary light-emitting diode LEDa), and each auxiliary data line DLa may be connected to the data driver 31. Accordingly, the auxiliary pixels Pxa (or the auxiliary light-emitting diodes LEDa) may be individually connected to the data driver 31 through the auxiliary data lines DLa that are provided.

Meanwhile, the auxiliary pixels Pxa or the auxiliary light-emitting diodes LEDa arranged along the x direction may be connected together to the same first electrode 21 and may be connected to the scan driver 32 through one auxiliary scan line SLa.

Compared to the embodiments of FIG. 12A, the embodiments of FIGS. 20 and 21 do not include the second electrode 22 but may include a larger number of auxiliary data lines DLa. According to some embodiments, the auxiliary data line DLa may include a conductive material.

Referring to FIG. 21, in order to prevent or reduce a transmittance in the component area CA from being lowered due to the auxiliary data line DLa, the auxiliary data line DLa may include a different material according to an area where the auxiliary data line DLa is located. According to some embodiments, a portion of the auxiliary data line DLa located in the main display area MDA or the peripheral are PA may include a metal. According to some embodiments, a portion of the auxiliary data line DLa located in the component area CA may include a transparent conductive oxide.

Comparing FIGS. 20 and 21, FIG. 20 illustrates embodiments where the auxiliary data line DLa entirely includes a metal, and FIG. 21 illustrates embodiments where a portion of the auxiliary data line DLa located in the main display area MDA or the peripheral area PA includes a metal and a portion of the auxiliary data line DLa located in the component area CA includes a transparent conductive oxide. To illustrate this, in FIG. 21, the auxiliary data line DLa in the component area CA is shown by a dashed line.

As described above, a configuration including a different material according to an area may also be applied to the auxiliary scan line SLa as well as the auxiliary data line DLa. For example, a portion of the auxiliary scan line SLa located in the main display area MDA may include a transparent conductive oxide, and a portion located in the peripheral area PA may include a metal. Also, as described above, a configuration including a different material according to an area where the auxiliary data line DLa and/or the auxiliary scan line SLa is located may also be applied to the embodiments described with reference to FIGS. 12A to 19.

Referring to FIGS. 22A and 22B, like in the embodiments of FIGS. 20 and 21, the auxiliary pixels Pxa or the auxiliary light-emitting diodes LEDa may be individually connected to the data driver 31.

As shown in FIG. 22B, the auxiliary data line DLa corresponding to each auxiliary light-emitting diode LEDa may be provided. The auxiliary pixel electrode 113a of the auxiliary light-emitting diode LEDa may be connected to the corresponding auxiliary data line DLa through an opening defined in the fifth insulating layer 109 and the sixth insulating layer 111.

According to some embodiments, the first electrode 21 (see FIG. 20) and the auxiliary scan line SLa (see FIG. 20) may be omitted. Accordingly, the auxiliary pixel Pxa or the auxiliary light-emitting diode LEDa may not be connected to the scan driver 32. In other words, the auxiliary pixel Pxa or the auxiliary light-emitting diode LEDa may be separated from the scan driver 32.

The sixth conductive layer 115 may be integrally formed over the entire main display area MDA and component area CA. The sixth conductive layer 115 may include the counter electrode 115m corresponding to the main light-emitting diode LEDm and an auxiliary counter electrode 115a corresponding to the auxiliary light-emitting diode LEDa. In other words, a portion of the sixth conductive layer 115 corresponding to the main light-emitting diode LEDm (or a portion overlapping the main pixel electrode 113m) may be the counter electrode 115m, and a portion corresponding to the auxiliary light-emitting diode LEDa (or a portion overlapping the auxiliary pixel electrode 113a) may be the auxiliary counter electrode 115a.

Because the counter electrode 115m and the auxiliary counter electrode 115a may be integrally formed, the auxiliary counter electrode 115a may receive the common voltage EVLSS (see FIG. 11) provided to the counter electrode 115m through the common voltage supply wiring 37 (see FIG. 11). The auxiliary light-emitting diode LEDa may receive the common voltage EVLSS from the auxiliary counter electrode 115a, and may receive a voltage from the data driver 31 through the auxiliary data line DLa, and the intermediate layer 114a may emit light due to a difference between the two voltages.

According to some embodiments, the sixth conductive layer 115 may include an opening corresponding to the transmissive area TA of the component area CA. In other words, the sixth conductive layer 115 may entirely cover the main display area MDA, but may be patterned to correspond to each auxiliary pixel Pxa or each auxiliary light-emitting diode LEDa in the component area CA. That is, each auxiliary counter electrode 115a may be patterned to overlap the auxiliary pixel electrode 113a. In this case, for example, the sixth conductive layer 115 may be provided in a mesh shape in the component area CA so that each auxiliary counter electrode 115a is connected to a part of the sixth conductive layer 115 (i.e., the counter electrode 115m) located in the main display area MDA. In other words, the sixth conductive layer 115 may entirely cover the main display area MDA and may be provided in a mesh shape in the component area, a part of the sixth conductive layer 115 located in the main display area MDA may be the counter electrode 115m, and a part of the sixth conductive layer 115 located in the component area CA may be the auxiliary counter electrode 115a.

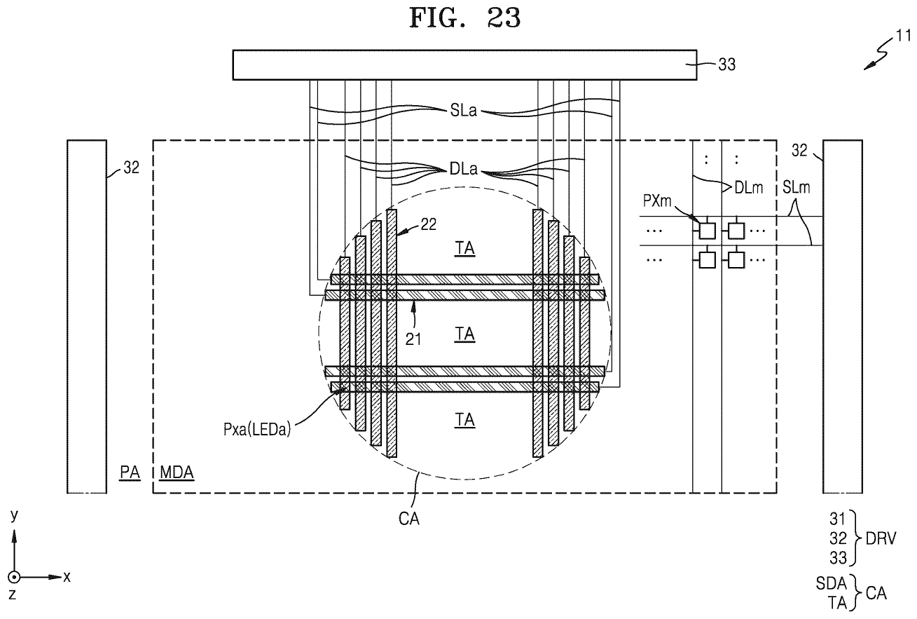

FIG. 23 is an enlarged plan view illustrating a portion of the display panel 11, according to some embodiments.

Referring to FIG. 23, the driver DRV may further include an auxiliary driver 33. The auxiliary pixels Pxa or the auxiliary light-emitting diodes LEDa may be connected to the auxiliary driver 33 without being connected to the data driver 31 or the scan driver 32. In other words, the auxiliary pixels Pxa or the auxiliary light-emitting diodes LEDa may be separated from the data driver 31 or the scan driver 32 and may be connected to the auxiliary driver 33.

A plurality of first electrodes 21 may be connected to the auxiliary driver 33 without being connected to the scan driver 32. In other words, the plurality of first electrodes 21 may be separated from the scan driver 32 and may be connected to the auxiliary driver 33. A plurality of second electrodes 22 may be connected to the auxiliary driver 33 without being connected to the data driver 31. In other words, the plurality of second electrodes 22 may be separated from the data driver 31 and may be connected to the auxiliary driver 33.

The main pixels Pxm may be connected to the data driver 31 and the scan driver 32 through the main data line DLm and the main scan line SLm. The main pixels Pxm may be driven by the data driver 31 and the scan driver 32, and the auxiliary pixels Pxa may be driven by the auxiliary driver 33. In other words, according to some embodiments, the auxiliary pixels Pxa may not be driven by the data driver 31 and the scan driver 32 for driving the main pixels Pxm, but may be driven by a separately provided driver (e.g., the auxiliary driver 33). Accordingly, the main pixels Pxm and the auxiliary pixels Pxa may be independently driven.

According to some embodiments, the auxiliary driver 33 may be arranged in the +y direction of the component area CA and the main display area MDA. Both the auxiliary data lines DLa and the auxiliary scan lines SLa may extend along the y direction and may be connected to the auxiliary driver 33. In other words, the auxiliary data lines DLa and the auxiliary scan lines SLa may extend along the same direction.

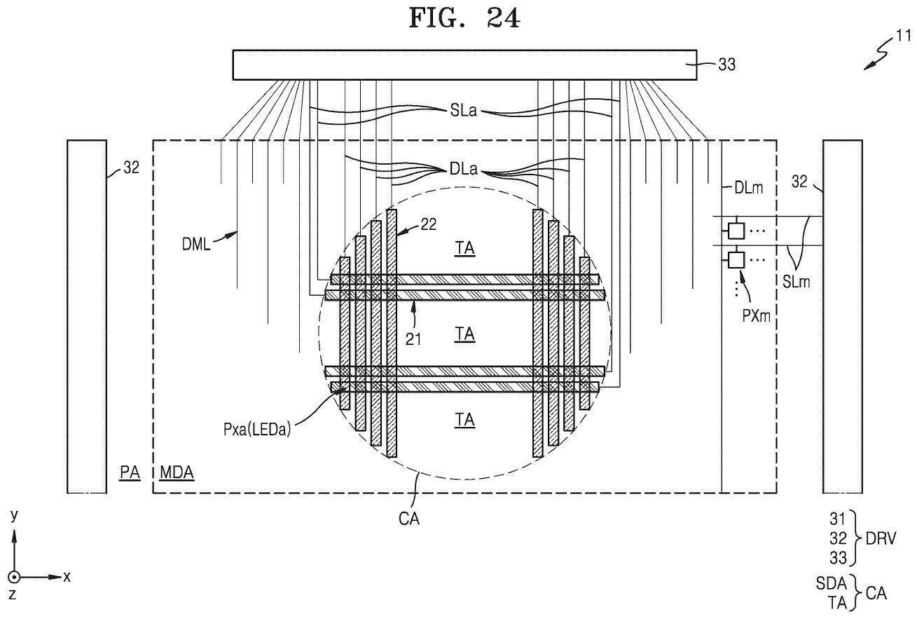

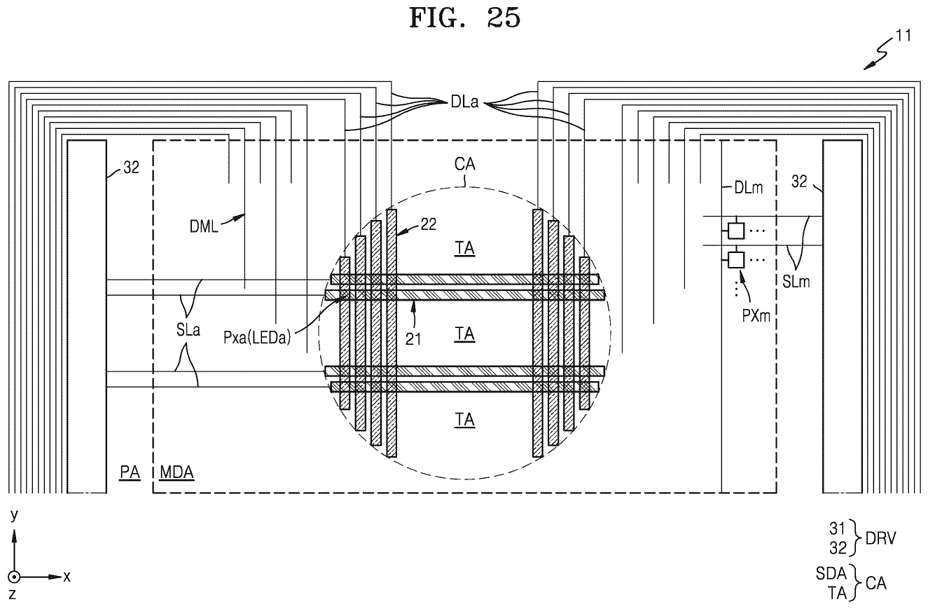

FIG. 24 is an enlarged plan view illustrating a portion of the display panel 11, according to some embodiments. FIG. 25 is an enlarged plan view illustrating a portion of the display panel 11, according to some embodiments.

Referring to FIGS. 24 and 25, the display panel 11 may include at least one dummy driving line DML. According to some embodiments, the display panel 11 may include a plurality of dummy driving lines DML. The dummy driving lines DML may be located adjacent to the component area CA. According to some embodiments, the dummy driving lines DML may generally extend along the y direction. According to some embodiments, a y-direction length of the dummy driving lines DML may decrease away from the component area CA.

The dummy driving lines DML may not be connected to the main pixel Pxm and/or the auxiliary pixel Pxa, but may be connected to the driver DRV.

Referring to FIG. 24, the dummy driving lines DML may be connected to the auxiliary driver 33. The embodiments of FIG. 24 may be embodiments obtained by adding the dummy driving lines DML to the embodiments of FIG. 23. Accordingly, features of the embodiments of FIG. 24 other than features related to the dummy driving line DML may be substantially the same as those described with reference to FIG. 23.

Referring to FIG. 25, the dummy driving lines DML may extend in the peripheral area PA and may be connected to the data driver 31. The embodiments of FIG. 25 may be embodiments obtained by adding the dummy driving lines DML to the embodiments of FIG. 12A. Accordingly, features of the embodiments of FIG. 25 other than features related to the dummy driving line DML may be substantially the same as those described with reference to FIG. 12A. According to some embodiments, at least some (e.g., all) of the dummy driving lines DML may be connected to the scan driver 32.

The main scan line SLm and the main data line DLm may be located even in a portion of the main display area MDA where the auxiliary scan line SLa and the auxiliary data line DLa are located. Accordingly, the portion may have higher wiring density than other portions, and an image quality difference from the other portions may occur due to coupling effect or interference between wirings arranged at a high density. According to some embodiments, the main display area MDA arranged in the +y direction of the component area CA of FIGS. 24 and 25 may have such an image quality difference. When a drastic image quality difference occurs between portions, the image quality difference may be perceived by a user (e.g., as a line).

When the dummy driving lines DML are located as shown in FIGS. 24 and 25, a wiring density in a portion where the auxiliary scan line SLa and/or the auxiliary data line DLa is not located may be increased. According to some embodiments, image quality in a second area where the dummy driving lines DML are additionally located may be inferior to that in a first area where only the main pixels Pxm, the main scan lines SLm, and the main data lines DLm are located. According to some embodiments, image quality in a third area where the auxiliary scan lines SLa and the auxiliary data lines DLa are additionally located may be inferior to that in the second area. When the dummy driving lines DML are not located, image quality may rapidly deteriorate from the first area toward the third area. On the other hand, when the second area is provided by arranging the dummy driving lines DML, image quality may relatively gradually change from the first area through the second area to the third area. In other words, a drastic image quality between portions of the display panel 11 may be prevented (or at least reduced) by arranging the dummy driving lines DML.

According to some embodiments as described above, there may be provided a display panel that performs active matrix driving in a main display area and performs passive matrix driving in a component area and an electronic device including the display panel. In the display panel, because there is no need to arrange a thin-film transistor for driving an auxiliary pixel located in the component area (e.g., in or near the component area), the component area may have a relatively improved transmittance.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope as defined by the following claims, and their equivalents.

What is claimed is:

1. A display panel comprising:
a substrate comprising a component area, a main display area at least partially surrounding the component area, and a non-display area at least partially surrounding the main display area;
main pixels in the main display area, comprising main light-emitting diodes, and configured to perform active matrix driving;
auxiliary pixels in the component area, comprising auxiliary light-emitting diodes, and configured to perform passive matrix driving; and
a driver in the non-display area and comprising a scan driver and a data driver,
wherein the auxiliary light-emitting diodes of the auxiliary pixels are directly connected to the driver.

2. The display panel of claim 1, further comprising:
a plurality of first electrodes spaced apart from each other in the component area and extending in a first direction;
a plurality of auxiliary scan lines connecting the plurality of first electrodes to the scan driver;
a plurality of second electrodes spaced apart from each other in the component area and extending in a second direction intersecting the first direction; and
a plurality of auxiliary data lines connecting the plurality of second electrodes to the data driver,
wherein the auxiliary light-emitting diodes are in areas where the plurality of first electrodes and the plurality of second electrodes intersect each other.

3. The display panel of claim 2, wherein one of the auxiliary light-emitting diodes comprises
an auxiliary pixel electrode in an area where one of the plurality of first electrodes and one of the plurality of second electrodes intersect each other,
an auxiliary intermediate layer on the auxiliary pixel electrode, and
a portion of the first electrode overlapping the auxiliary pixel electrode.

4. The display panel of claim 3, further comprising a bank layer on the auxiliary pixel electrode and covering an edge portion of the auxiliary pixel electrode,
wherein the plurality of first electrodes are spaced apart from each other with the bank layer therebetween.

5. The display panel of claim 4, wherein the bank layer comprises a first bank layer and a second bank layer on the first bank layer,
wherein the plurality of first electrodes cover a part of the first bank layer and are spaced apart from each other with the second bank layer therebetween.

6. The display panel of claim 4, further comprising an anti-adhesive layer on a top surface of the bank layer.

7. The display panel of claim 3, wherein the second electrode is under the auxiliary pixel electrode,
wherein one of the plurality of auxiliary data lines is under the second electrode, and
the auxiliary pixel electrode is connected to the auxiliary data line through the second electrode.

8. The display panel of claim 3, wherein the second electrode is integrally formed with the auxiliary pixel electrode.

9. The display panel of claim 3, wherein the second electrode is integrally formed with one of the plurality of auxiliary data lines.

10. The display panel of claim 2, wherein a width of each of the plurality of first electrodes and each of the plurality of second electrodes in a first portion where the plurality of first electrodes and the plurality of second electrodes intersect each other is greater than a width of each of the plurality of first electrodes and each of the plurality of second electrodes in a second portion other than the first portion.

11. The display panel of claim 2, wherein at least some of the plurality of auxiliary scan lines extend along a circumference of the main display area and are connected to the scan driver.

12. The display panel of claim 1, wherein the auxiliary light-emitting diodes are individually connected to the data driver.

13. The display panel of claim 12, further comprising a first electrode in the component area and extending in a first direction,
wherein a plurality of auxiliary light-emitting diodes overlap the first electrode, and
the plurality of auxiliary light-emitting diodes overlapping the first electrode are connected together to the scan driver through the first electrode.

14. The display panel of claim 12, wherein
each of the main light-emitting diodes comprises a main pixel electrode, a main intermediate layer on the main pixel electrode, and a counter electrode on the main intermediate layer, and
the auxiliary light-emitting diodes are separated from the scan driver and are connected to the counter electrode.

15. The display panel of claim 1, wherein the driver further comprises an auxiliary driver,
wherein the auxiliary light-emitting diodes of the auxiliary pixels are separated from the scan driver and the data driver and are connected to the auxiliary driver.

16. The display panel of claim 1, further comprising at least one dummy driving line adjacent to the component area, connected to the driver, and separated from the main pixels and the auxiliary pixels.

17. A display panel comprising:
a substrate comprising a component area, a main display area at least partially surrounding the component area, and a non-display area at least partially surrounding the main display area;
a main light-emitting diode in the main display area;
an auxiliary light-emitting diode in the component area; and
a driver in the non-display area and comprising a scan driver and a data driver,
wherein the main light-emitting diode is connected to the driver through a pixel circuit comprising at least one thin-film transistor, and
the auxiliary light-emitting diode is directly connected to the driver.

18. An electronic device comprising a display panel,
wherein the display panel comprises:
a substrate comprising a component area, a main display area at least partially surrounding the component area, and a non-display area at least partially surrounding the main display area;
main pixels in the main display area, comprising main light-emitting diodes, and configured to perform active matrix driving;
auxiliary pixels in the component area, comprising auxiliary light-emitting diodes, and configured to perform passive matrix driving; and
a driver in the non-display area and comprising a scan driver and a data driver,
wherein the auxiliary light-emitting diodes of the auxiliary pixels are directly connected to the driver.

19. The electronic device of claim 18, wherein the display panel further comprises:
a plurality of first electrodes spaced apart from each other in the component area and extending in a first direction;
a plurality of auxiliary scan lines connecting the plurality of first electrodes to the scan driver;
a plurality of second electrodes spaced apart from each other in the component area and extending in a second direction intersecting the first direction; and
a plurality of auxiliary data lines connecting the plurality of second electrodes to the data driver,
wherein the auxiliary light-emitting diodes are in areas where the plurality of first electrodes and the plurality of second areas intersect each other.

20. The electronic device of claim 18, wherein the auxiliary light-emitting diodes are individually connected to the data driver.
